(19) United States
(12) Patent Application Publication
(10) Pub. No.: US 2026/0082714 A1
(43) Pub. Date: Mar. 19, 2026

(54) PHOTODETECTION DEVICE AND ELECTRONIC APPARATUS

(71) Applicant: SONY SEMICONDUCTOR SOLUTIONS CORPORATION, KANAGAWA (JP)

(72) Inventor: IPPEI YOSHIBA, KANAGAWA (JP)

(21) Appl. No.: 19/108,837

(22) PCT Filed: Sep. 5, 2023
(86) PCT No.: PCT/JP2023/032397

§ 371 Date: Mar. 5, 2025

(30) Foreign Application Priority Data
Sep. 13, 2022 (JP) 2022-145227

(51) Int. Cl. H10F 39/00

(52) U.S. Cl. CPC H10F 39/8063; H10F 39/8037; H10F 39/8053; H10F 39/8057

(57) ABSTRACT

Provided is a photodetection device capable of suppressing deterioration of a captured image. A photodetection device includes: a semiconductor layer including a plurality of cell regions arranged in a row direction and a column direction in a pixel region, one surface of the semiconductor layer being an element formation surface, and another surface of the semiconductor layer being a light incident surface; and a deflection layer provided at a position facing the light incident surface of the cell region or provided in a portion of the cell region on the light incident surface side. A photoelectric conversion element, a light shielding film extending along a direction perpendicular to a thickness direction of the semiconductor layer, and a charge holding unit located closer to the element formation surface than the light shielding film in a thickness direction of the semiconductor layer are provided in the cell region. The deflection layer includes, for each of the cell regions, a first region having a first refractive index and a second region having a second refractive index higher than the first refractive index at different positions in plan view. The second region is located at a position overlapping the light shielding film in plan view.

### TECHNICAL FIELD

The present technology (technology according to the present disclosure) relates to a photodetection device and an electronic apparatus, and particularly relates to a photodetection device and an electronic apparatus each including a charge holding unit.

### BACKGROUND ART

A solid-state imaging device of a global shutter system in which a charge holding unit that holds a charge transferred from a photoelectric converter is provided in a pixel separately from a floating diffusion has been developed. In such a solid-state imaging device, when light is incident on the charge holding unit, noise called parasitic light sensitivity (PLS) may occur in the charge holding unit. Therefore, a light shielding film may be provided so that light is not incident on the charge holding unit (for example, Patent Document 1).

### CITATION LIST

### Patent Document

Patent Document 1: Japanese Patent Application Laid-open No. 2013-098446

### SUMMARY OF THE INVENTION

### Problems to be Solved by the Invention

In a solid-state imaging device, an output of a pixel may change depending on an incident angle of light. An object of the present technology is to provide a photodetection device and an electronic apparatus capable of suppressing deterioration of a captured image.

### Solutions to Problems

A photodetection device according to one aspect of the present technology includes: a semiconductor layer including a plurality of cell regions arranged in a row direction and a column direction in a pixel region, one surface of the semiconductor layer being an element formation surface, and another surface of the semiconductor layer being a light incident surface; and a deflection layer provided at a position facing the light incident surface of the cell region or provided in a portion of the cell region on the light incident surface side. A photoelectric conversion element, a light shielding film extending along a direction perpendicular to a thickness direction of the semiconductor layer, and a charge holding unit located closer to the element formation surface than the light shielding film in a thickness direction of the semiconductor layer are provided in the cell region. The deflection layer includes, for each of the cell regions, a first region having a first refractive index and a second region having a second refractive index higher than the first refractive index at different positions in plan view. The second region is located at a position overlapping the light shielding film in plan view.

An electronic apparatus according to one aspect of the present technology includes the above photodetection device, and an optical system that causes the photodetection device to form an image with image light from a subject.

### BRIEF DESCRIPTION OF DRAWINGS

FIG. 1 is a chip layout diagram illustrating an example configuration of a photodetection device according to a first embodiment of the present technology.

FIG. 2 is a block diagram illustrating an example configuration of the photodetection device according to the first embodiment of the present technology.

FIG. 3 is an equivalent circuit diagram of pixels of the photodetection device according to the first embodiment of the present technology.

FIG. 4A is a longitudinal cross-sectional view illustrating a cross-sectional configuration of a pixel of the photodetection device according to the first embodiment of the present technology.

FIG. 4B is an explanatory view illustrating a state in which a main light beam is deflected by a deflection layer in the photodetection device according to the first embodiment of the present technology.

FIG. 4C is a transverse cross-sectional view illustrating a positional relationship among a partition wall, a light shielding film, and a second region when viewed in a cross section taken along line A-A in FIG. 4A.

FIG. 4D is an explanatory view illustrating a positional relationship among a first light shielding film, a second light shielding film, and a charge holding unit in the photodetection device according to the first embodiment of the present technology.

FIG. 4E is an explanatory view illustrating a main light beam deflected in a pixel in the photodetection device according to the first embodiment of the present technology.

FIG. 5A is a process cross-sectional view illustrating a method for manufacturing the photodetection device according to the first embodiment of the present technology.

FIG. 5B is a process cross-sectional view subsequent to FIG. 5A.

FIG. 5C is a process cross-sectional view subsequent to FIG. 5B.

FIG. 5D is a process cross-sectional view subsequent to FIG. 5C.

FIG. 5E is a process cross-sectional view subsequent to FIG. 5D.

FIG. 5F is a process cross-sectional view subsequent to FIG. 5E.

FIG. 5G is a process cross-sectional view subsequent to FIG. 5F.

FIG. 5H is a process cross-sectional view subsequent to FIG. 5G.

FIG. 5I is a process cross-sectional view subsequent to FIG. 5H.

FIG. 5J is a process cross-sectional view subsequent to FIG. 5I.

FIG. 6A is an explanatory view illustrating a main light beam traveling in a pixel in a photodetection device having no deflection layer.

FIG. 6B is a diagram illustrating a relationship between the output of a pixel 3 and the incident angle of the main light beam in the photodetection device having no deflection layer.

FIG. 7 is a diagram illustrating a relationship between the output of the pixel 3 and the incident angle of the main light beam in the photodetection device according to the first embodiment of the present technology.

FIG. 8A is a plan view illustrating a planar shape of a second region according to a first modification of the first embodiment of the present technology.

FIG. 8B is a plan view illustrating a planar shape of the second region according to the first modification of the first embodiment of the present technology.

FIG. 9 is a longitudinal cross-sectional view illustrating a cross-sectional configuration of a pixel of a photodetection device according to a second modification of the first embodiment of the present technology.

FIG. 10A is a process cross-sectional view illustrating a method for manufacturing the photodetection device according to the second modification of the first embodiment of the present technology.

FIG. 10B is a process cross-sectional view subsequent to FIG. 10A.

FIG. 10C is a process cross-sectional view subsequent to FIG. 10B.

FIG. 11 is a longitudinal cross-sectional view illustrating a cross-sectional configuration of a pixel of a photodetection device according to a third modification of the first embodiment of the present technology.

FIG. 12A is a process cross-sectional view illustrating a method for manufacturing the photodetection device according to the third modification of the first embodiment of the present technology.

FIG. 12B is a process cross-sectional view subsequent to FIG. 12A.

FIG. 13A is a longitudinal cross-sectional view illustrating a cross-sectional configuration of a pixel of a photodetection device according to a fourth modification of the first embodiment of the present technology.

FIG. 13B is a transverse cross-sectional view illustrating a positional relationship among a partition wall, a light shielding film, and a second region when viewed in a cross section taken along line A-A in FIG. 13A.

FIG. 14A is a longitudinal cross-sectional view illustrating a cross-sectional configuration of a pixel of a photodetection device according to a second embodiment of the present technology.

FIG. 14B is a transverse cross-sectional view of a pixel showing the distribution of the columnar bodies when viewed in a cross section taken along line A-A in FIG. 14A.

FIG. 15A is a process cross-sectional view illustrating a method for manufacturing the photodetection device according to the second embodiment of the present technology.

FIG. 15B is a process cross-sectional view subsequent to FIG. 15A.

FIG. 15C is a process cross-sectional view subsequent to FIG. 15B.

FIG. 15D is a process cross-sectional view subsequent to FIG. 15C.

FIG. 16 is a transverse cross-sectional view of pixels showing distribution of columnar bodies in a photodetection device according to a first modification of the second embodiment of the present technology.

FIG. 17 is a transverse cross-sectional view of pixels showing distribution of columnar bodies in a photodetection device according to a second modification of the second embodiment of the present technology.

FIG. 18 is a transverse cross-sectional view of pixels showing distribution of columnar bodies in a photodetection device according to a third modification of the second embodiment of the present technology.

FIG. 19 is an explanatory view for explaining pupil correction in a photodetection device according to a third embodiment of the present technology.

FIG. 20 is a longitudinal cross-sectional view illustrating a cross-sectional configuration of a pixel of a photodetection device according to a fourth embodiment of the present technology.

FIG. 21A is a transverse cross-sectional view of a pixel showing a planar shape of a partition wall of the photodetection device according to the fourth embodiment of the present technology.

FIG. 21B is a transverse cross-sectional view of a pixel showing a planar shape of a partition wall of the photodetection device according to the fourth embodiment of the present technology.

FIG. 22 is a block diagram illustrating an example of a schematic configuration of an electronic apparatus.

FIG. 23 is a block diagram illustrating an example of a schematic configuration of a vehicle control system.

FIG. 24 is an explanatory view illustrating an example of installation positions of an outside-vehicle information detecting section and an imaging section.

FIG. 25 is a view illustrating an example of a schematic configuration of an endoscopic surgery system.

FIG. 26 is a block diagram depicting an example of a functional configuration of a camera head and a camera control unit (CCU).

### MODE FOR CARRYING OUT THE INVENTION

Hereinafter, embodiments of the present disclosure will be described with reference to the drawings. In the description of the drawings referred to in the following description, the same or similar parts are denoted by the same or similar reference signs to avoid the description from being redundant. However, it should be noted that the drawings are schematic, and the relationship between thickness and planar dimension, the proportion of thickness of each device or each member, and the like differ from actual ones. Therefore, specific thicknesses and dimensions should be determined in consideration of the following description. Furthermore, it goes without saying that dimensional relationships and ratios are partly different between the drawings. Furthermore, since the drawings suitable for describing the present technology are adopted, there may be a difference in configuration between the drawings.

Furthermore, the definitions of directions such as up and down or the like in the following description are merely definitions for convenience of description, and do not limit the technical idea of the present disclosure. For example, it goes without saying that if a target is observed while being rotated by 90°, the upward and downward directions are converted into rightward and leftward, and if the target is observed while being rotated by 180°, the upward and downward are inverted.

Note that the effects described in the present specification are merely examples and are not limited, and other effects may be provided.

Explanation will be made in the following order.

### 1. First Embodiment

### 2. Second Embodiment

### 3. Third Embodiment

### 4. Fourth Embodiment

### 5. Fifth Embodiment

Example Application to an Electronic Apparatus
Example Application to a Mobile Body
Example Application to an Endoscopic Surgery System

### First Embodiment

In this embodiment, an example in which the present technology is applied to a photodetection device that is a back-illuminated complementary metal oxide semiconductor (CMOS) image sensor is described.

### <<Overall Configuration of Photodetection Device>>

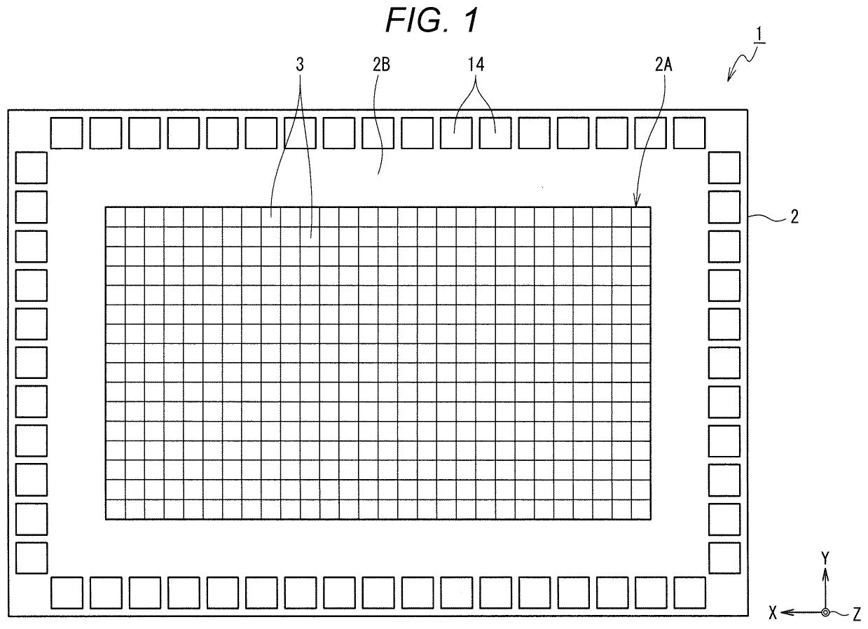

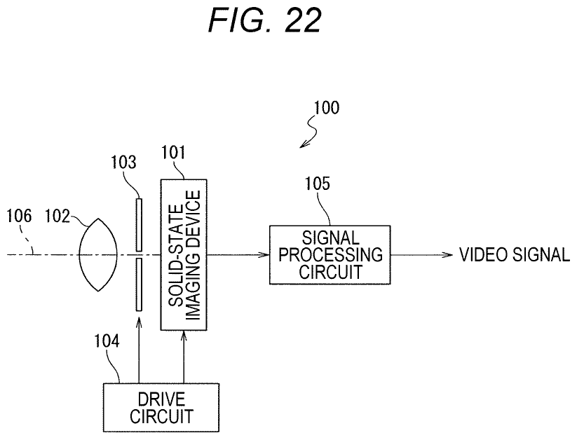

First, an overall configuration of a photodetection device 1 is described. As illustrated in FIG. 1, the photodetection device 1 according to the first embodiment of the present technology is formed mainly with a semiconductor chip 2 having a rectangular two-dimensional planar shape in plan view. That is, the photodetection device 1 is mounted on the semiconductor chip 2. As illustrated in FIG. 22, the photodetection device 1 captures image light (incident light 106) from a subject via an optical system (optical lens) 102, converts the amount of the incident light 106 formed as an image on the imaging surface into an electrical signal pixel by pixel, and outputs the electrical signal as a pixel signal.

As illustrated in FIG. 1, the semiconductor chip 2 on which the photodetection device 1 is mounted includes, in a two-dimensional plane including an X direction and a Y direction intersecting each other, a rectangular pixel region 2A provided in a central portion, and a peripheral region 2B provided outside the pixel region 2A to surround the pixel region 2A.

The pixel region 2A is a light-receiving surface that receives light condensed by an optical system 102 illustrated in FIG. 22, for example. Then, in the pixel region 2A, a plurality of pixels 3 is arranged in a matrix in the two-dimensional plane including the X direction and the Y direction. In other words, the pixels 3 are repeatedly disposed in each of the X direction and the Y direction intersecting each other in the two-dimensional plane. Note that, in the present embodiment, the X direction and the Y direction are orthogonal to each other, for example. Furthermore, a direction orthogonal to both the X direction and the Y direction is a Z direction (thickness direction, stacking direction). Furthermore, a direction perpendicular to the Z direction is a horizontal direction.

As illustrated in FIG. 1, a plurality of bonding pads 14 is disposed in the peripheral region 2B. Each bonding pad of the plurality of bonding pads 14 is disposed along each of the four sides of the two-dimensional plane of the semiconductor chip 2, for example. Each bonding pad of the plurality of bonding pads 14 is an input-output terminal that is used when the semiconductor chip 2 is electrically connected to an external device.

### <Global Shutter System>

The photodetection device 1 employs a global shutter system. The global shutter system is basically a method for performing global exposure in which exposure is started simultaneously for all pixels and exposure is terminated simultaneously for all pixels. Here, all the pixels mean all the pixels in a portion appearing in the image, and dummy pixels and the like are excluded. Furthermore, if a time difference and distortion of the image are sufficiently small so as not to increase, a method for moving an area where global exposure is performed while performing global exposure in units of a plurality of rows (for example, several tens of rows) instead of all pixels at the same time is also included in the global shutter system. Furthermore, the global shutter system also includes a method for performing global exposure on pixels in a predetermined area instead of all the pixels in the portion appearing in the image.

### <Logic Circuit>

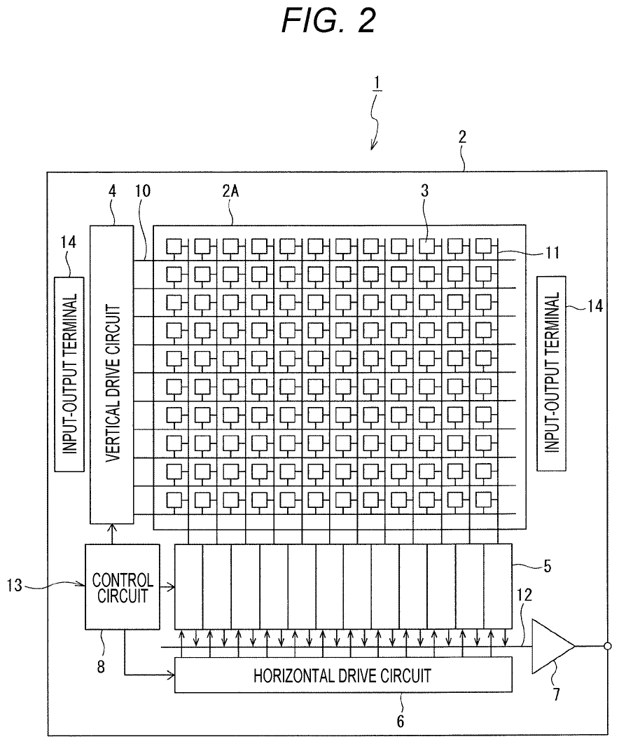

The semiconductor chip 2 includes a logic circuit 13 illustrated in FIG. 2. The logic circuit 13 includes a vertical drive circuit 4, column signal processing circuits 5, a horizontal drive circuit 6, an output circuit 7, a control circuit 8, and the like. The logic circuit 13 includes a complementary MOS (CMOS) circuit including an n-channel conductive metal oxide semiconductor field effect transistor (MOSFET) and a p-channel conductive MOSFET as field effect transistors, for example.

The vertical drive circuit 4 includes a shift register, for example. The vertical drive circuit 4 sequentially selects a desired pixel drive line 10, supplies a pulse for driving the pixels 3 to the selected pixel drive line 10, and drives the respective pixels 3 row by row. That is, the vertical drive circuit 4 selectively scans each of the pixels 3 in the pixel region 2A sequentially in a vertical direction on a row-by-row basis, and supplies a pixel signal from each of the pixels 3 based on a signal charge generated in accordance with the amount of received light by a photoelectric conversion element of the pixel 3 to the column signal processing circuit 5 through a vertical signal line (VSL) 11.

The column signal processing circuits 5 are disposed on the respective columns of the pixels 3, for example, and perform, for the respective pixel columns, signal processing such as noise removal on signals to be outputted from the pixels 3 of one row. For example, each column signal processing circuit 5 performs signal processing such as correlated double sampling (CDS) for removing pixel-specific fixed pattern noise, and analog-to-digital (AD) conversion. A horizontal selection switch (not shown) is disposed in the output stage of each column signal processing circuit 5, and is connected to a horizontal signal line 12.

The horizontal drive circuit 6 includes a shift register, for example. The horizontal drive circuit 6 sequentially outputs horizontal scanning pulses to the column signal processing circuits 5 to sequentially select each of the column signal processing circuits 5, and causes each of the column signal processing circuits 5 to output a pixel signal subjected to signal processing to the horizontal signal line 12.

The output circuit 7 performs signal processing on pixel signals sequentially supplied from the respective column signal processing circuits 5 through the horizontal signal line 12, and outputs a processed signal. As the signal processing, buffering, black level adjustment, column variation correction, various kinds of digital signal processing, and the like can be used, for example.

The control circuit 8 generates a clock signal and a control signal that are references for operations of the vertical drive circuit 4, the column signal processing circuits 5, the horizontal drive circuit 6, and the like, on the basis of a vertical synchronization signal, a horizontal synchronization signal, and a master clock signal. Then, the control circuit 8 then outputs the generated clock signal and control signal to the vertical drive circuit 4, the column signal processing circuits 5, the horizontal drive circuit 6, and the like.

### <Pixel>

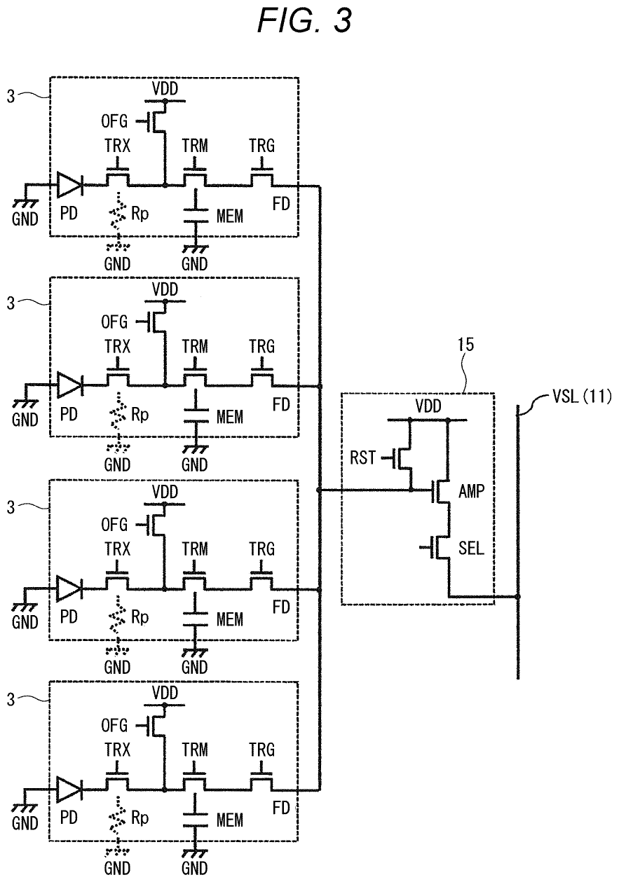

FIG. 3 is an equivalent circuit diagram illustrating a configuration example of the pixel 3. The pixel 3 includes, for example, a photoelectric conversion element PD, a first transfer transistor TRX, a second transfer transistor TRM, a charge holding unit MEM, a third transfer transistor TRG, a charge accumulation region (floating diffusion) FD, and a discharge transistor OFG. Furthermore, the pixel 3 includes a reading circuit 15 electrically connected via the charge accumulation region FD. The reading circuit 15 outputs a pixel signal based on the electric charges output from the pixel 3. In the illustrated example, the reading circuit 15 is provided for every four pixels 3. That is, the four pixels 3 share one reading circuit 15. Here, “sharing” means that the outputs of the four pixels 3 are input to the same reading circuit 15. The reading circuit 15 includes, for example, a reset transistor RST, a selection transistor SEL, and an amplification transistor AMP.

The photoelectric conversion element PD photoelectrically converts the incident light. The photoelectric conversion element PD generates electric charges corresponding to an amount of received light by photoelectric conversion. The photoelectric conversion element PD has a cathode electrically connected to a source of the first transfer transistor TRX and an anode electrically connected to a reference potential line (for example, ground GND).

The first transfer transistor TRX is a first transistor that is connected between the photoelectric conversion element PD and the second transfer transistor TRM and transfers the electric charges accumulated in the photoelectric conversion element PD to the second transfer transistor TRM according to a control signal applied to a gate electrode (vertical gate electrode TRXG). The first transfer transistor TRX transfers electric charges from the photoelectric conversion element PD to the charge holding unit MEM. The first transfer transistor TRX includes the vertical gate electrode TRXG. The drain of the first transfer transistor TRX is electrically connected to the source of the second transfer transistor TRM, and the gate of the first transfer transistor TRX is connected to the pixel drive line.

The second transfer transistor TRM is connected between the first transfer transistor TRX and the third transfer transistor TRG, and controls a potential of the charge holding unit MEM in accordance with a control signal applied to a gate electrode. For example, when the second transfer transistor TRM is turned on, the potential of the charge holding unit MEM becomes deep, and when the second transfer transistor TRM is turned off, the potential of the charge holding unit MEM becomes shallow. Then, for example, when the first transfer transistor TRX and the second transfer transistor TRM are turned on, the electric charges accumulated in the photoelectric conversion element PD is transferred to the charge holding unit MEM via the first transfer transistor TRX and the second transfer transistor TRM. The drain of the second transfer transistor TRM is electrically connected to the third transfer transistor TRG, and the gate of the second transfer transistor TRM is connected to the pixel drive line.

The charge holding unit MEM is a diffusion region that temporarily holds the electric charges accumulated in the photoelectric conversion element PD in order to achieve the global shutter function. The charge holding unit MEM holds the electric charges transferred from the photoelectric conversion element PD.

The third transfer transistor TRG is a second transistor that is connected between the second transfer transistor TRM and the charge accumulation region FD and transfers the electric charges held in the charge holding unit MEM to the charge accumulation region FD according to a control signal applied to the gate electrode. For example, when the second transfer transistor TRM is turned off and the third transfer transistor TRG is turned on, the electric charges held in the charge holding unit MEM is transferred to the charge accumulation region FD via the second transfer transistor TRM and the third transfer transistor TRG. The drain of the third transfer transistor TRG is electrically connected to the charge accumulation region FD, and the gate of the third transfer transistor TRG is connected to the pixel drive line.

The charge accumulation region FD is a diffusion region that temporarily holds the electric charges output from the photoelectric conversion element PD via the third transfer transistor TRG, more specifically, a floating diffusion region. The reset transistor RST is, for example, connected to the charge accumulation region FD, and is connected to the vertical signal line VSL (11) through the amplification transistor AMP and the selection transistor SEL.

The drain of the discharge transistor OFG is connected to a power supply line VDD, and the source is connected between the first transfer transistor TRX and the second transfer transistor TRM. The discharge transistor OFG initializes (resets) the photoelectric conversion element PD according to a control signal applied to the gate electrode. For example, when the first transfer transistor TRX and the discharge transistor OFG are turned on, the potential of the photoelectric conversion element PD is reset to the potential level of the power supply line VDD. That is, the photoelectric conversion element PD is initialized. Furthermore, for example, the discharge transistor OFG forms an overflow path between the first transfer transistor TRX and the power supply line VDD, and discharges electric charges overflowing from the photoelectric conversion element PD to the power supply line VDD.

In the reset transistor RST, the drain is connected to the power supply line VDD, and the source is connected to the charge accumulation region FD. The reset transistor RST initializes (resets) each region from the charge holding unit MEM to the charge accumulation region FD according to a control signal applied to the gate electrode. For example, when the third transfer transistor TRG and the reset transistor RST are turned on, the potentials of the charge holding unit MEM and the charge accumulation region FD are reset to the potential level of the power supply line VDD. That is, the charge holding unit MEM and the charge accumulation region FD are initialized.

The amplification transistor AMP has a gate electrode connected to the charge accumulation region FD and a drain connected to the power supply line VDD, and serves as an input unit of a source-follower circuit that reads the electric charges obtained by the photoelectric conversion in the photoelectric conversion element PD. That is, the amplification transistor AMP has the source connected to the vertical signal line VSL via the selection transistor SEL, thereby forming a source-follower circuit with a constant current source connected to one end of the vertical signal line VSL.

The selection transistor SEL is connected between the source of the amplification transistor AMP and the vertical signal line VSL, and a control signal is supplied to the gate electrode of the selection transistor SEL as a selection signal. When the control signal is turned on, the selection transistor SEL is brought into conduction, and the pixel 3 coupled to the selection transistor SEL is brought into a selected state. When the pixel 3 is brought into the selected state, the pixel signal output from the amplification transistor AMP is read out by the column signal processing circuit 5 via the vertical signal line VSL.

### <<Specific Configuration of Photodetection Device>>

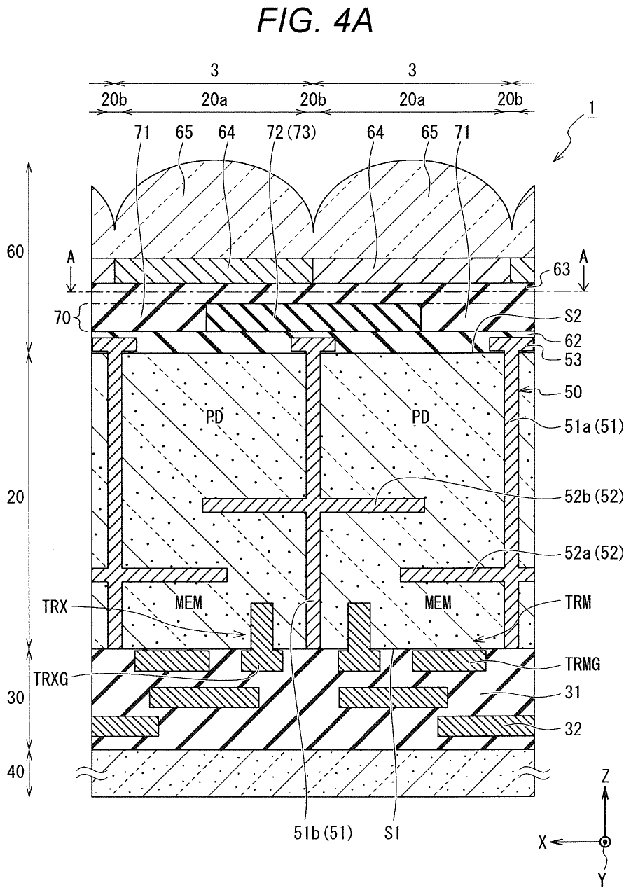

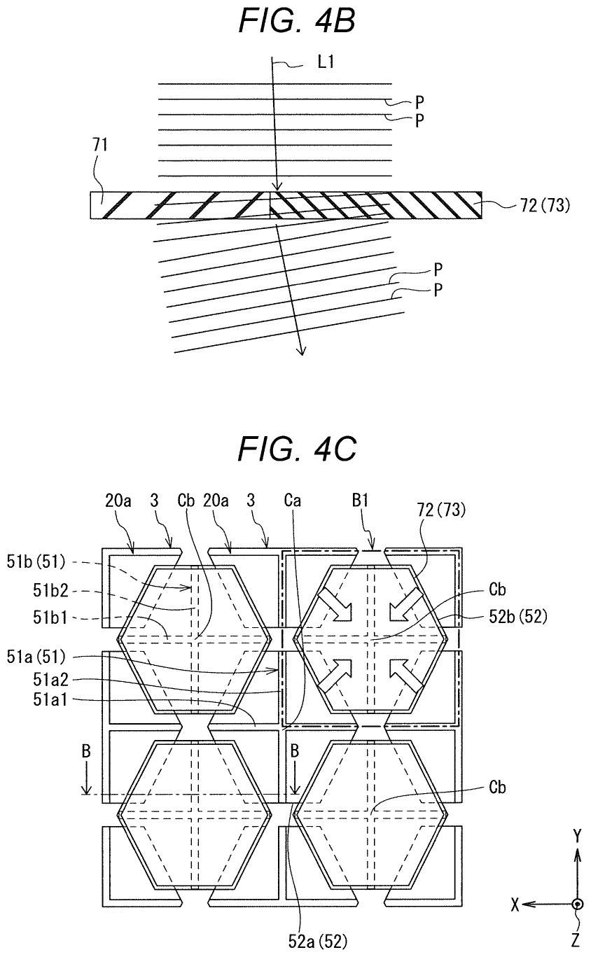

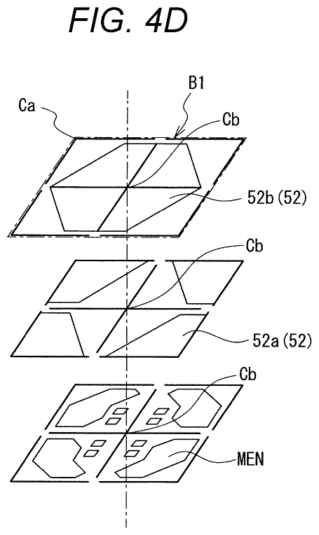

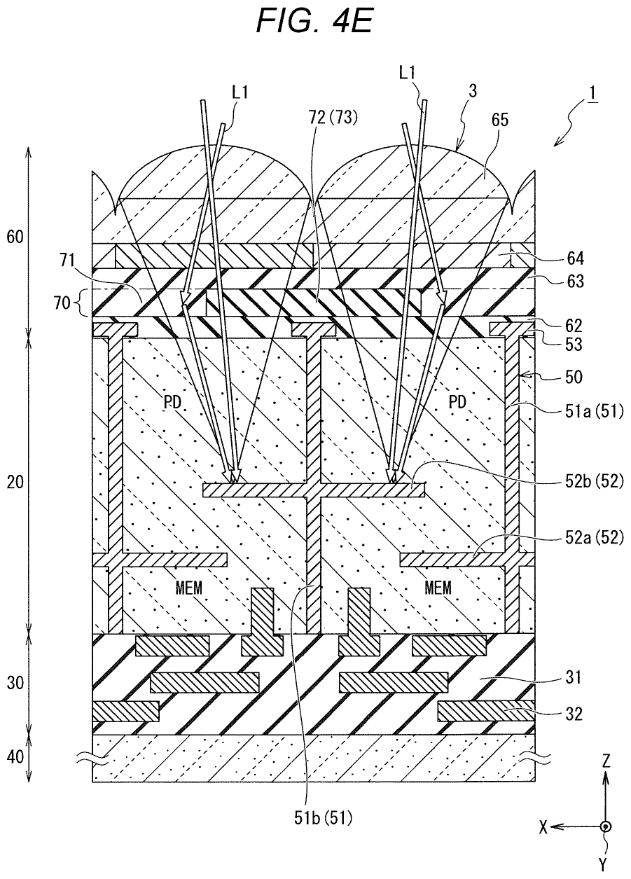

Next, a specific configuration of the photodetection device 1 is described with reference to FIGS. 4A to 4E. FIG. 4A illustrates a cross-sectional configuration of the pixel 3 when viewed in a cross-sectional view taken along line B-B in FIG. 4C. Note that, in FIG. 4A and subsequent drawings, illustration of a pinning layer covering an exposed surface of a semiconductor layer, an insulation film insulating a metal material and a semiconductor layer 20, and the like may be omitted.

### <Multilayer Structure of Photodetection Device>

As illustrated in FIG. 4A, the semiconductor chip 2 on which the photodetection device 1 is mounted has a multilayer structure in which a light incident surface side multilayer body 60, a semiconductor layer 20, a wiring layer 30, and a support substrate 40 are stacked in this order. The light incident surface side multilayer body 60 includes a deflection layer 70. Although not limited thereto, the light incident surface side multilayer body 60 has, for example, a multilayer structure in which an insulating layer 62, a deflection layer 70, an insulating layer 63, a color filter 64, and a microlens 65 that is an on-chip lens are stacked in this order from the second surface S2 side. The semiconductor layer 20 will be described below.

### <Semiconductor Layer>

The semiconductor layer 20 includes a semiconductor substrate. Although not limited thereto, the semiconductor layer 20 includes, for example, a single crystal silicon substrate, and one surface is a first surface S1 and the other surface is a second surface S2. Note that, the second surface S2 may be referred to as a light incident surface or a back surface, and the first surface S1 may be referred to as an element formation surface or a main surface. A plurality of cell regions 20a arranged in the row direction and the column direction is provided in a portion corresponding to the pixel region 2A of the semiconductor layer 20. The cell region 20a is provided for each pixel 3. For example, as illustrated in FIG. 4A, an island-shaped cell region 20a partitioned by an isolation region 20b is provided for each pixel 3 in a portion corresponding to the pixel region 2A of the semiconductor layer 20. Then, the isolation region 20b has, for example, a trench structure in which a groove is formed in the semiconductor layer 20 along the thickness direction, and a material constituting a partition wall 51 to be described later is embedded in the formed groove. The cell region 20a has a semiconductor region of a first conductivity type (for example, p-type) and a semiconductor region of a second conductivity type (for example, n-type) for each cell region 20a, and photoelectric conversion is performed in a partial region in the cell region 20a. Furthermore, the number of pixels 3 is not limited to the number shown in FIG. 4A.

FIG. 4C illustrates a positional relationship among the partition wall 51, a light shielding film 52 to be described later, and a second region 72 to be described later when viewed in a cross-sectional view taken along line A-A in FIG. 4A. Furthermore, FIG. 4C illustrates an example in which pixels of four rows and four columns are extracted from the plurality of pixels 3. The cell region 20a is, for example, a quadrangle such as a square or a rectangle in plan view. Then, four cell regions 20a in two rows and two columns constitute one cell region assembly B1. Then, the semiconductor layer 20 includes a plurality of cell region assemblies B1 arranged in the row direction and the column direction. Among the four corners of the cell region 20a in plan view, a corner located closer to the corner of the cell region assembly B1 may be referred to as a first corner in order to be distinguished from the other three corners. Furthermore, among the four corners of the cell region 20a in plan view, a corner located closer to the center of the cell region assembly B1 may be referred to as a second corner in order to be distinguished from the other three corners. Furthermore, the first corner and the second corner are corners facing each other in the diagonal direction of the cell region 20a. Note that, in a case where the first corner and the second corner are not distinguished from each other, they are simply referred to as corners.

In a portion of the semiconductor layer 20 corresponding to the pixel region 2A, for example, the photoelectric conversion element PD, the diffusion region, various transistors, and the like illustrated in FIG. 3 are configured. For example, in the example illustrated in FIG. 4A, among such elements and diffusion regions, at least the photoelectric conversion element PD, the charge holding unit MEM, the first transfer transistor TRX, and the second transfer transistor TRM are configured in each cell region 20a. The charge holding unit MEM is located closer to the first surface S1 (closer to the element formation surface) than a light shielding film 52 described later, more specifically a first light shielding film 52a in the thickness direction of the semiconductor layer 20. Note that, in FIG. 4A and subsequent drawings, illustration of at least some elements, diffusion regions, and the like may be omitted.

### <Light Shielding Unit>

A light shielding unit 50 includes a partition wall 51, a light shielding film 52, and an inter-pixel light-shielding film 53. The partition wall 51 will be described below. As illustrated in FIG. 4A, the partition wall 51 has a trench structure extending along the thickness direction (Z direction) of the semiconductor layer 20 and partitioning between the cell regions 20a. In the present embodiment, the partition wall 51 is a full trench isolation (FTI). As illustrated in FIG. 4C, a portion of the partition wall 51 extending along the Z direction and the X direction partitions between the cell regions 20a adjacent in the Y direction, and a portion extending along the z direction and the Y direction partitions between the cell regions 20a adjacent in the X direction.

The partition wall 51 includes a first partition wall 51a and a second partition wall 51b. The first partition wall 51a includes a wall 51a1 extending along the Z direction and the X direction, and a wall 51a2 extending along the Z direction and the Y direction and intersecting the wall 51a1. The wall 51a1 and the wall 51a2 intersect each other at the central portion, and the first partition wall 51a has a cross shape in plan view. Similarly, the second partition wall 51b has a wall 51b1 extending along the Z direction and the X direction, and a wall 51b2 extending along the Z direction and the Y direction and intersecting the wall 51b1. The wall 51b1 and the wall 51b2 intersect each other at the central portion, and the second partition wall 51b has a cross shape in plan view. Note that, in a case where the first partition wall 51a and the second partition wall 51b are not distinguished from each other, they are simply referred to as partition walls 51. Furthermore, in plan view, an intersection between the wall 51a1 and the wall 51a2 is referred to as a cross center Ca, and an intersection between the wall 51b1 and the wall 51b2 is referred to as a cross center Cb. The cross center Cb is located near the center of cell region assembly B1, and is located at a point where four second corners are gathered. Then, the cross center Ca is located near a corner of the cell region assembly B1, and is located at a point where four first corners are gathered.

The first partition wall 51a and the second partition wall 51b are provided with a space therebetween and are not connected to each other. Then, the first partition wall 51a and the second partition wall 51b are alternately arrayed along the diagonal direction in plan view of the cell region 20a. More specifically, in plan view, the cross center Ca and the cross center Cb are alternately arranged along the diagonal direction of the cell region 20a. Furthermore, a plurality of cross centers Ca and a plurality of cross centers Cb are arranged along the row direction and the column direction, respectively. With such a configuration, in one cell region 20a, two adjacent sides among four sides in plan view are partitioned by the first partition wall 51a, and the remaining two adjacent sides are partitioned by the second partition wall 51b.

The light shielding film 52 is provided to make it difficult for the light incident on the cell region 20a to be incident on the charge holding unit MEM. As illustrated in FIG. 4A, the light shielding film 52 extends along a direction (horizontal direction) perpendicular to the thickness direction (Z direction) of the semiconductor layer 20 and is connected to the partition wall 51. The light shielding film 52 includes a first light shielding film 52a and a second light shielding film 52b located closer to the second surface S2 (light incident surface) than the first light shielding film 52a in the thickness direction. In other words, the second light shielding film 52b is connected to the partition wall 51 at a position closer to the second surface S2 than the first light shielding film 52a. Then, as illustrated in FIG. 4C, in plan view, the first light shielding film 52a is on one side of the cell region 20a, and the second light shielding film 52b is on the other side of the cell region 20a. More specifically, one side of the cell region 20a is a first corner side, and is a corner side of the cell region assembly B1. Furthermore, the other side of the cell region 20a is the second corner side, and is the center side of the cell region assembly B1. Note that, in a case where the first light shielding film 52a and the second light shielding film 52b are not distinguished from each other, they are simply referred to as light shielding films 52.

The first light shielding film 52a extends along the horizontal direction from the wall 51a1 and the wall 51a2 of the first partition wall 51a. More specifically, the first light shielding film 52a radially extends over the cell region 20a of two rows and two columns around the cross center Ca in plan view, and has a hexagonal shape together with the first partition wall 51a. Note that the first light shielding film 52a does not reach the second corner. Furthermore, the second light shielding film 52b extends along the horizontal direction from the wall 51b1 and the wall 51b2 of the second partition wall 51b. More specifically, the second light shielding film 52b radially extends over the cell region 20a of two rows and two columns around the cross center Cb in plan view, and has a hexagonal shape together with the second partition wall 51b. Note that the second light shielding film 52b does not reach the first corner.

As illustrated in FIG. 4D, the charge holding unit MEM is at a position closer to one of the one side and the other side of the cell region 20a, more specifically, at a position closer to the first corner (cross center Ca) of the first corner and the second corner in plan view. Then, the first light shielding film 52a is at a position overlapping the charge holding unit MEM in plan view. In other words, the first light shielding film 52a is provided at a position overlapping the charge holding unit MEM in plan view. Furthermore, as illustrated in FIG. 4C, since the first light shielding film 52a and the second light shielding film 52b partially overlap each other in plan view, the light incident on the cell region 20a is less likely to be incident on the charge holding unit MEM.

As illustrated in FIG. 4A, the inter-pixel light-shielding film 53 is disposed closer to the semiconductor layer 20 side than the microlens 65 in the region of the boundary between the pixels 3, and shields stray light leaking from adjacent pixels. More specifically, the inter-pixel light-shielding film 53 is provided along an end portion of the partition wall 51 on the second surface S2 side.

The light shielding unit 50 desirably contains a material that shields light. The light shielding unit 50 is not limited thereto, but may contain a metal material such as tungsten, aluminum, or copper, for example. In a case where the light shielding unit 50 includes a conductive material, it is necessary to insulate the semiconductor layer 20 from the light shielding unit with an insulation film. The insulation film is not limited thereto, and examples thereof include silicon oxide. Furthermore, a plurality of members among the partition wall 51, the light shielding film 52, and the inter-pixel light-shielding film 53 may contain the same material. In the present embodiment, a case where all the members of the partition wall 51, the light shielding film 52, and the inter-pixel light-shielding film 53 contain tungsten will be described.

### <Deflection Layer>

As illustrated in FIG. 4A, the deflection layer 70 is provided at a position facing the second surface S2 (light incident surface) of the cell region 20a in the Z direction. The deflection layer 70 includes a first region 71 having a first refractive index and a second region 72 having a second refractive index higher than the first refractive index at different positions in plan view for each cell region 20a, and the second region 72 is at a position overlapping the light shielding film 52 in plan view. More specifically, the second region 72 is at a position overlapping the second light shielding film 52b in plan view. Furthermore, in one cell region 20a, the first light shielding film 52a and the first region 71 are on one side of the cell region 20a, and the second light shielding film 52b and the second region 72 are on the other side of the cell region 20a in plan view. Then, the first light shielding film 52a and the first region 71 are at positions overlapping the charge holding unit MEM in plan view. In other words, the deflection layer 70 includes the first region 71 having the first refractive index at a position overlapping the first light shielding film 52a in plan view, and includes the second region 72 having the second refractive index higher than the first refractive index at a position overlapping the second light shielding film 52b. Note that, in the present embodiment, the second regions 72 included in the cell regions 20a of two rows and two columns are collectively configured by one continuous flat plate-like member 73. The thickness of the member 73 is substantially uniform and does not change significantly. Furthermore, the first regions 71 included in the cell regions 20a of two rows and two columns are collectively constituted by continuous members constituting a part of the insulating layer 63. Note that FIG. 4A illustrates the first region 71 within the illustrated range. The first region 71 is, for example, a portion embedded (positioned) between the second regions 72 of the insulating layer 63.

A main light beam L1 incident on the photodetection device 1 passes through the deflection layer 70 and then is incident on the cell region 20a. In general, light travels slower in a medium having a high refractive index than in a medium having a low refractive index. Therefore, as illustrated in FIG. 4B, the traveling speed of the main light beam L1 incident on the deflection layer 70 in the second region 72 becomes slower than the traveling speed in the first region 71. More specifically, a wavefront P of the main light beam L1 travels slower in the second region 72 than in the first region 71. As a result, the wavefront P of the main light beam L1 is deflected, and the main light beam L1 is deflected toward a direction in which the second region 72 out of the first region 71 and the second region 72 exists in plan view. Then, as illustrated in FIG. 4E, since the second region 72 is at a position overlapping the second light shielding film 52b in plan view, the main light beam L1 is deflected in each cell region 20a in a direction in which the second light shielding film 52b of the first light shielding film 52a and the second light shielding film 52b is present in plan view. More specifically, the main light beam L1 is deflected from the first light shielding film 52a toward the second light shielding film 52b in each cell region 20a. That is, the main light beam L1 is deflected toward the other side of one side and the other side of the cell region 20a.

Therefore, the main light beam L1 obliquely incident on the pixel 3 is deflected by the deflection layer 70 toward the second light shielding film 52b located on the other side of the cell region 20a. For example, the main light beam L1 obliquely incident on the pixel 3 toward the first light shielding film 52a located on one side of the cell region 20a is deflected toward the second light shielding film 52b located on the other side of the cell region 20a by the deflection layer 70. Therefore, the amount of light reaching the first light shielding film 52a can be suppressed. The main light beam L1 is obliquely incident on the pixel 3, for example, in a case where the pixel 3 is at a position where the image height of the pixel region 2A is high or in a case where the F value of the optical system is small. Even in such a case, since the main light beam L1 is deflected toward the second light shielding film 52b by the deflection layer 70, it becomes difficult for the main light beam L1 to reach the first light shielding film 52a.

Furthermore, even in a case where the main light beam L1 is incident on the pixel 3 straight along the Z direction, the main light beam L1 is deflected toward the second light shielding film 52b located on the other side of the cell region 20a by the deflection layer 70. The main light beam L1 is incident on the pixel 3 straight along the Z direction, for example, in a case where the pixel 3 is at the center of the image height of the pixel region 2A. Even in such a case, since the main light beam L1 is deflected toward the second light shielding film 52b by the deflection layer 70, it becomes difficult for the main light beam L1 to reach the first light shielding film 52a.

Furthermore, as illustrated in FIG. 4C, in the present embodiment, the second regions 72 (members 73) of the deflection layer 70 are collectively provided for each cell region assembly B1, and have a hexagonal shape in plan view. Furthermore, the second region 72 (member 73) of the deflection layer 70 is at a position overlapping all (four) second corners for each cell region assembly B1 in plan view. More specifically, in plan view, the second region 72 is at a position overlapping the cross center Cb located at the center of the cell region assembly B1, and is at a position overlapping all four second corners adjacent to the cross center Cb. Furthermore, although not denoted by a reference sign in FIG. 4C, a region other than the second region 72 corresponds to the first region 71 in plan view. Therefore, as indicated by the arrow in FIG. 4C, the main light beam L1 is deflected toward the second corner adjacent to the cross center Cb of the first corner and the second corner in each cell region 20a in plan view. More specifically, the main light beam L1 is deflected from the first corner toward the second corner in each cell region 20a.

Note that the deflection characteristic is improved in a case where one second region 72 is provided for the four cell regions 20a of two rows and two columns as compared with a case where the second region 72 is provided for each cell region 20a. For example, by providing one second region 72, the same effect can be obtained in each of the cell regions 20a of two rows and two columns arranged in the mirror target. Furthermore, by providing the second region 72 across the cell region 20a, the region of the second region 72 is widened, and the effect of deflecting light is further increased.

The deflection layer 70 includes a first material and a second material having a higher refractive index than the first material, the first region 71 contains the first material, and the second region 72, that is, the member 73 contains the second material. Examples of the first material include, but are not limited to, a substance such as silicon oxide (SiO₂). Furthermore, examples of the second material include, but are not limited to, substances such as silicon nitride (Si₃N₄), silicon oxynitride (SiON), silicon carbide (SiC), zirconium oxide (Zro₂), titanium oxide (TiO₂), zinc sulfide (ZnS), and zinc oxide (ZnO).

### <Light Incident Surface Side Multilayer Body>

As illustrated in FIG. 4A, the insulating layer 62 of the light incident surface side multilayer body 60 contains a known insulating material, and is not limited thereto, but contains, for example, silicon oxide. The insulating layer 62 is stacked so as to cover the inter-pixel light-shielding film 53, and functions as a planarization film that planarizes irregularities due to the provision of the inter-pixel light-shielding film 53.

The insulating layer 63 is stacked so as to cover the second region 72 of the deflection layer 70, and functions as a planarization film that planarizes irregularities due to the provision of the second region 72. Furthermore, a portion of the insulating layer 63 embedded between the second regions 72, that is, a portion between the dash line illustrated in FIG. 4A and the surface of the insulating layer 62 closer to the microlens 65 in the present embodiment functions as the first region 71 of the deflection layer 70. The insulating layer 63 contains the first material.

The color filter 64 is provided for each cell region 20a (for each pixel 3) on the side opposite to the semiconductor layer 20 side of the deflection layer 70. The color filter 64 performs color separation on incident light on the cell region 20a. The color filter 64 performs color separation on visible light, for example. The color filter contains, for example, a resin material. The microlens 65 is provided for each pixel 3. The microlens 65 includes, for example, a resin material.

### <Wiring Layer and Support Substrate>

The wiring layer 30 is a multilayer wiring layer stacked on the first surface S1 of the semiconductor layer 20. The wiring layer 30 includes an insulation film 31, a wiring 32, a via (contact; not illustrated), and the like. The wiring 32 is stacked, with the insulation film 31 being interposed in between, as illustrated in the drawing. The insulation film 31 contains a known insulating material, and is not limited thereto, but contains, for example, silicon oxide. The wiring 32 contains a metal material. The material of the wiring layer 30 is not limited thereto, and examples thereof include copper (Cu) and aluminum (Al).

The support substrate 40 is provided on the side of the wiring layer 30 opposite to the semiconductor layer 20 side. The support substrate 40 is not limited thereto, but is, for example, a semiconductor substrate such as silicon.

### <<Method for Manufacturing Photodetection Device>>

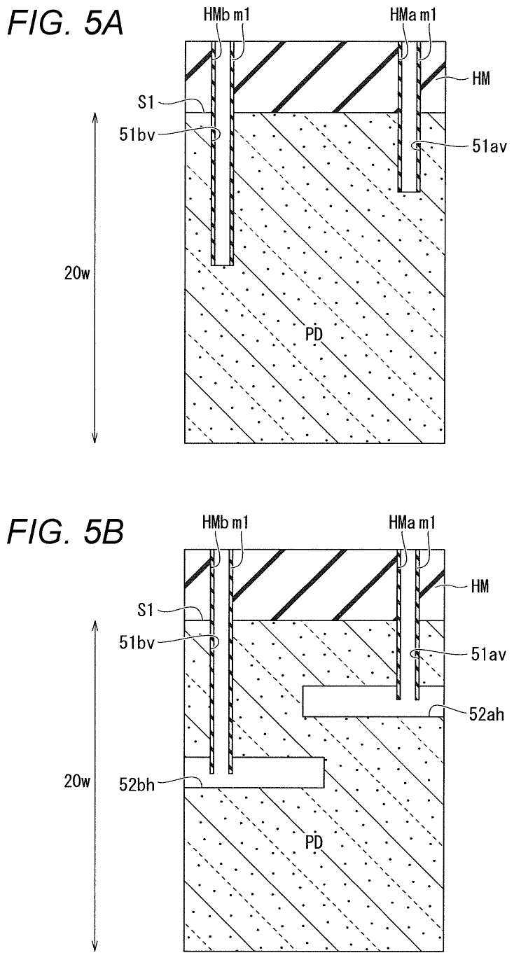

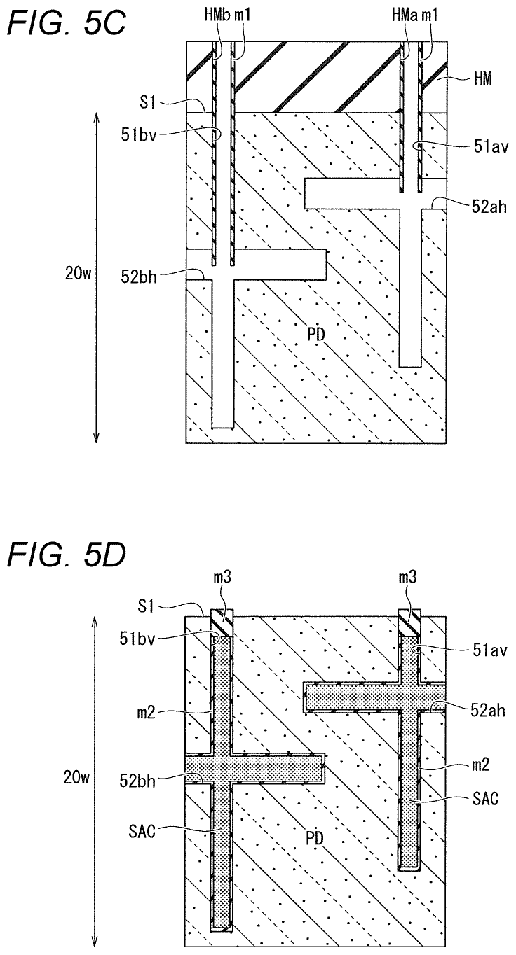

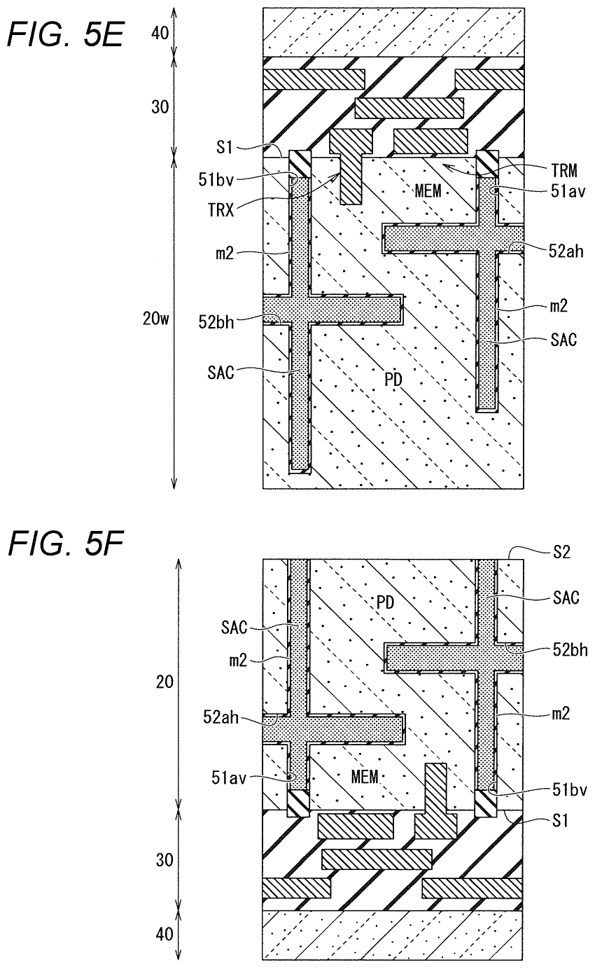

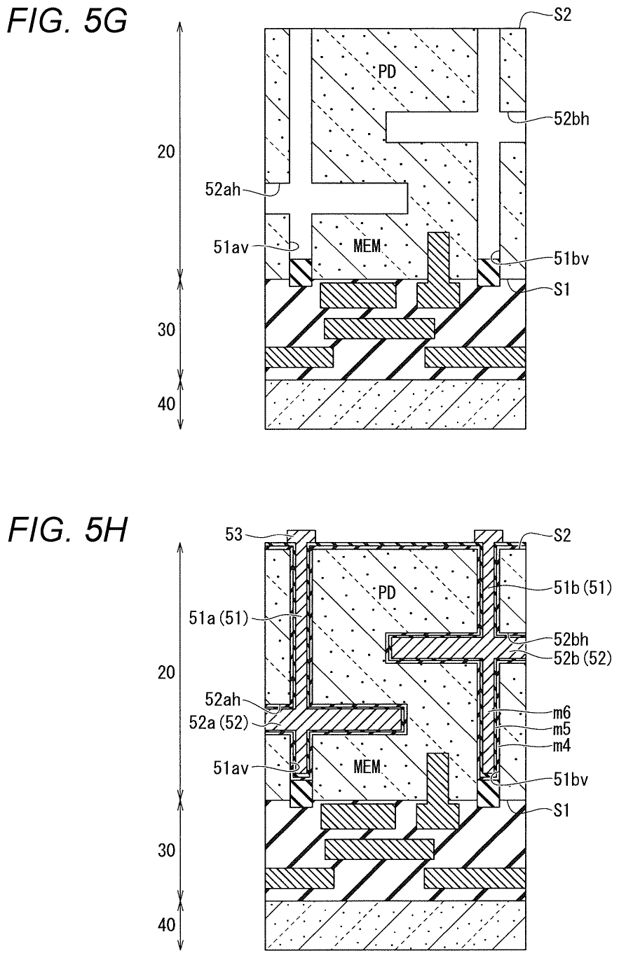

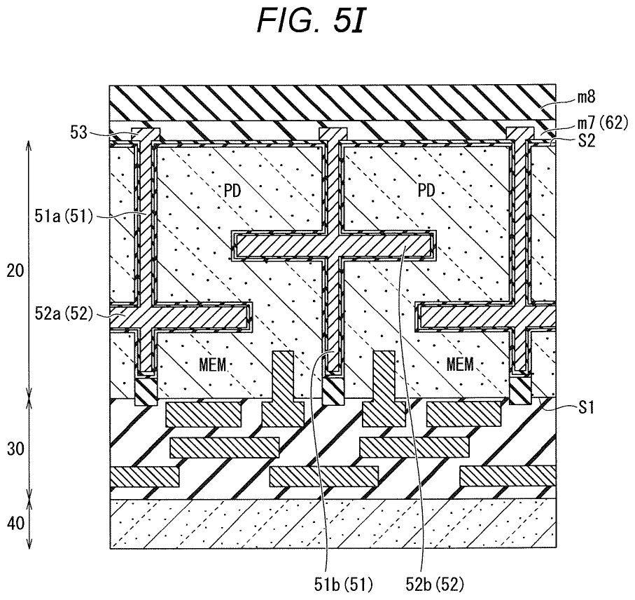

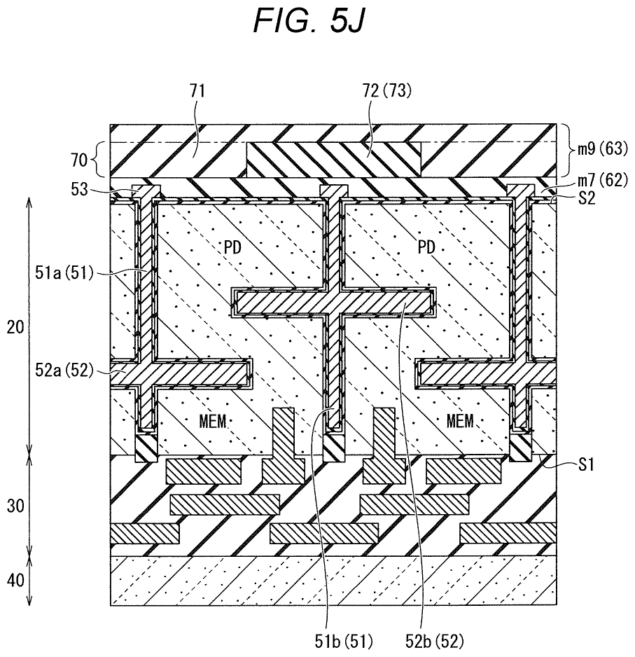

Hereinafter, a method for manufacturing the photodetection device 1 will be described with reference to FIGS. 5A to 5J. First, as illustrated in FIG. 5A, a substrate of a semiconductor layer 20w is prepared. In the semiconductor layer 20w, a semiconductor region of the first conductivity type and a semiconductor region of the second conductivity type are already formed at positions constituting the photoelectric conversion element PD. Furthermore, the substrate of the semiconductor layer 20w has a plane orientation <111> as the first surface S1. Then, a vertical groove 51av and a vertical groove 51bv having different depths are formed in the semiconductor layer 20w from the first surface S1 side by using a known lithography technique and etching technique (for example, reactive ion etching). The vertical groove 51av is formed at a position where the first partition wall 51a is provided in plan view, and the vertical groove 51bv is formed at a position where the second partition wall 51b is provided in plan view. The vertical groove 51av is provided up to the depth at which the first light shielding film 52a is formed via an opening HMa of a hard mask HM stacked on the first surface S1. Then, the vertical groove 51bv is provided up to the depth at which the second light shielding film 52b is formed via an opening HMb of the hard mask HM. The vertical groove 51bv is provided deeper than the vertical groove 51av. Such a difference in the depth of the groove can be formed by first filling the opening HMa of the hard mask HM with a photoresist and then etching a part of the vertical groove 51bv, and then removing the photoresist and etching both the vertical groove 51av and the vertical groove 51bv. Note that, in the crystalline anisotropic etching to be described later, the semiconductor layer 20w is somewhat etched in the <111> direction, and thus, it is desirable that the depths of the vertical grooves 51av and 51bv be set in consideration of the etching in the <111> direction.

Furthermore, as illustrated in FIG. 5A, a protective film m1 is formed on the side walls of the vertical grooves 51av and the vertical grooves 51bv. The protective film m1 is not limited thereto, but has, for example, silicon oxide or a multilayer structure of silicon nitride and silicon oxide. The protective film m1 may contain a material having an etching rate sufficiently lower than the etching rate of silicon in crystalline anisotropic etching described later. After the film formation, a portion of the protective film m1 located at the bottom portion of the vertical groove 51av and the vertical groove 51bv is removed by etch-back to form a sidewall.

Next, as illustrated in FIG. 5B, a lateral groove 52ah and a lateral groove 52bh extending along the horizontal direction are formed using a known crystalline anisotropic etching technique. The crystalline anisotropic etching technique is, for example, etching using an etching solution such as an alkaline aqueous solution, and the etching rate of the semiconductor layer 20w in the <110> direction is sufficiently higher than the etching rate in the <111> direction. Therefore, the lateral groove 52ah and the lateral groove 52bh extending along the horizontal direction can be formed.

Then, as illustrated in FIG. 5C, the vertical groove 51av and the vertical groove 51bv are dug deeper. More specifically, the workpiece goes deeper beyond the lateral groove 52ah and the lateral groove 52bh. Thereafter, the protective film m1 is removed.

Next, as illustrated in FIG. 5D, the exposed surfaces of the vertical grooves 51av and 51bv and the lateral grooves 52ah and 52bh are covered with an insulation film m2 using a known film forming technique such as an atomic layer deposition (ALD) method. The insulation film m2 is a known insulating material, and is not limited thereto, but is, for example, a silicon oxide film. Then, the cavity portions in the vertical grooves 51av and 51bv and the lateral grooves 52ah and 52bh are filled with a sacrificial film SAC. The sacrificial film SAC contains a material having a selected etchant and an etching rate sufficiently higher than the etching rate of the insulation film m2. The sacrificial film SAC is not limited thereto, but contains polysilicon, for example. Note that a portion of the cavity portion in the vicinity of the first surface S1 of the vertical grooves 51av and 51bv is filled with an insulation film m3 instead of the sacrificial film SAC and covered. The insulation film m3 is a known insulation film, and is not limited thereto, but is, for example, a silicon oxide film. Then, planarization is performed by a chemical mechanical polishing (CMP) method to remove the hard mask HM.

Thereafter, as illustrated in FIG. 5E, a diffusion region such as the charge holding unit MEM and elements such as various transistors are formed by impurity implantation. Then, the wiring layer 30 is formed on the first surface S1, and the support substrate 40 is bonded to the side of the wiring layer 30 opposite to the semiconductor layer 20w side.

Next, as illustrated in FIG. 5F, the semiconductor layer 20w is ground and thinned from the surface opposite to the first surface S1. The grinding is performed using a known method such as, but not limited to, a CMP method. This grinding leaves the semiconductor layer 20, and a surface obtained by the grinding is the second surface S2. Then, although not partially illustrated, as illustrated in FIG. 5G, the sacrificial film SAC is removed by wet etching using an alkaline solution through an opening of a hard mask (not illustrated), and then the hard mask (not illustrated) and the insulation film m2 are removed.

Thereafter, as illustrated in FIG. 5H, a pinning layer m4 and an insulation film m5 are sequentially stacked in this order on the exposed surfaces of the vertical grooves 51av and 51bv and the lateral grooves 52ah and 52bh, and then the cavity portions in the vertical grooves 51av and 51bv and the lateral grooves 52ah and 52bh are filled with a light shielding material m6. Examples of the material constituting the pinning layer m4 include, but are not limited to, hafnium oxide (HfO), zirconium oxide (ZrO₂), and tantalum oxide (Ta 05). The insulation film m5 is a known insulating material, and is not limited thereto, but is, for example, a silicon oxide film. The insulation film m5 is formed using a known film forming technique such as an ALD method. The light shielding material m6 is a material constituting the light shielding unit 50. The light shielding material m6 filled in the cavity portions in the vertical grooves 51av and 51bv constitutes the partition wall 51, and the light shielding material m6 filled in the cavity portions in the lateral grooves 52ah and 52bh constitutes the light shielding film 52. Thereafter, the inter-pixel light-shielding film 53 is formed on the second surface S2 side of the semiconductor layer 20 by using a known lithography technique and etching technique.

Next, as illustrated in FIG. 5I, an insulation film m7 is stacked so as to cover the inter-pixel light-shielding film 53, and the stacked insulation film m7 is planarized to obtain the insulating layer 62. Then, a film m8 containing the second material is formed on the exposed surface of the insulating layer 62. Then, as illustrated in FIG. 5J, the second region 72 (member 73) of the deflection layer 70 is obtained by removing an extra portion of the film m8 using a known lithography technique and etching technique. Thereafter, an insulation film m9 is stacked so as to cover the second region 72, and the stacked insulation film m9 is planarized to obtain the insulating layer 63. Then, a part of the insulating layer 63 constitutes the first region 71 of the deflection layer 70 as illustrated in the drawing.

Thereafter, the light incident surface side multilayer body 60 is formed, and the photodetection device 1 is almost completed. Then, the photodetection device 1 is singulated to obtain the semiconductor chip 2.

### Principal Effects of First Embodiment

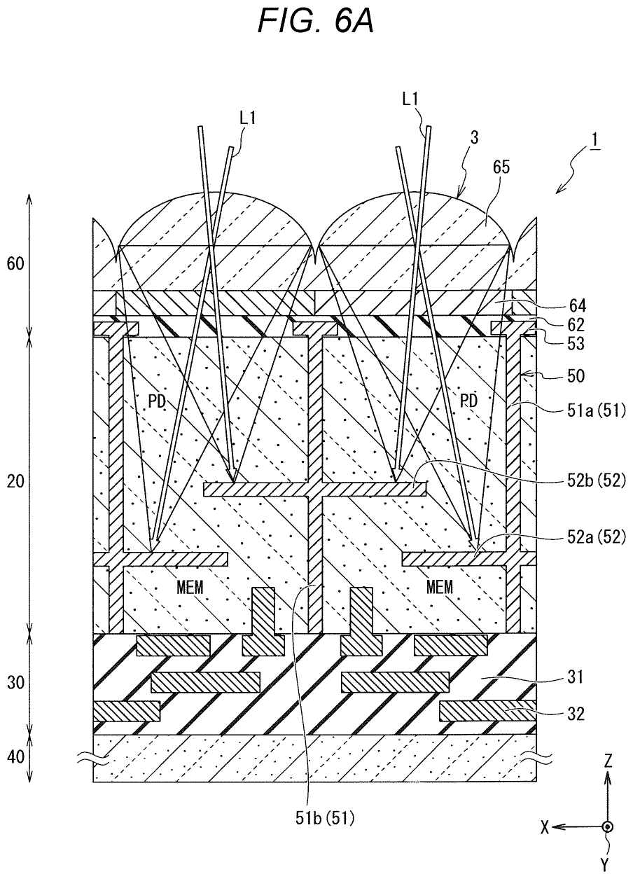

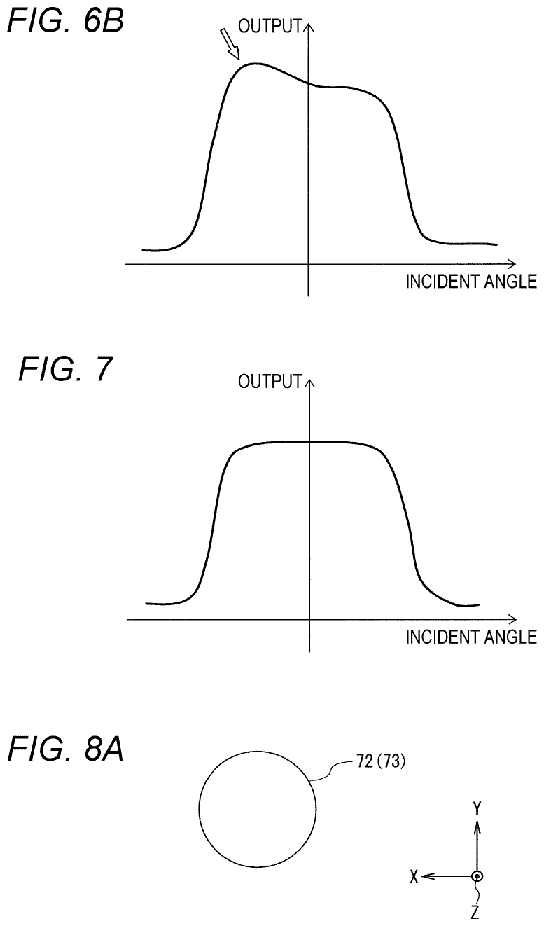

Hereinafter, a main effect of the first embodiment will be described. Before that, a photodetection device without the deflection layer 70 illustrated in FIG. 6A will be described. In the photodetection device illustrated in FIG. 6A, since the deflection layer 70 is not provided, the main light beam L1 is not deflected toward the second light shielding film 52b. Therefore, depending on the incident angle of the main light beam L1, there are a case where a large amount of the main light beam L1 hits the first light shielding film 52a of the first light shielding film 52a and the second light shielding film 52b, and a case where a large amount of the main light beam L1 hits the second light shielding film 52b. In a case where a large amount of the main light beam L1 hits the first light shielding film 52a, the optical path length is longer than that in a case where a large amount of the main light beam L1 hits the second light shielding film 52b, and the semiconductor layer 20 appears to be effectively thick, and the sensitivity is improved. Therefore, as illustrated in FIG. 6B, there is a possibility that asymmetry as indicated by an arrow occurs in the incident angle characteristic of the output of the pixel 3. More specifically, as indicated by an arrow, there has been a possibility that the output of the pixel 3 becomes large at a specific incident angle.

Then, due to such output asymmetry, there is a possibility that a difference in shading amount occurs between one side of the angle-of-view end and the other side of the angle-of-view end of the semiconductor chip 2 where the incident angle of the main light beam is obliquely incident. Note that the one side of the angle-of-view end and the other side of the angle-of-view end are the angle-of-view ends facing each other.

On the other hand, the photodetection device 1 according to the first embodiment of the present technology includes: a semiconductor layer 20 having the plurality of cell regions 20a arranged in a row direction and a column direction in the pixel region 2A, one surface of which is an element formation surface, and the other surface of which is a light incident surface; and the deflection layer 70 provided at a position facing the light incident surface of the cell region 20a, in which the photoelectric conversion element PD, the light shielding film 52 extending along a direction perpendicular to a thickness direction of the semiconductor layer 20, and the charge holding unit MEM located closer to the element formation surface than the light shielding film 52 in the thickness direction of the semiconductor layer 20 are provided in the cell region 20a, and the deflection layer 70 includes, for each cell region 20a, the first region 71 having a first refractive index at a different position in plan view, and, the second region 72 having a second refractive index higher than the first refractive index, and the second region 72 is at a position overlapping the light shielding film 52 in plan view. Since the photodetection device 1 has such a configuration, the main light beam L1 is deflected toward the light shielding film 52 overlapping the second region 72 in plan view due to the refractive index difference between the first region 71 and the second region 72.

More specifically, in the photodetection device 1 according to the first embodiment of the present technology, the light shielding film 52 includes the first light shielding film 52a and the second light shielding film 52b located closer to the light incident surface than the first light shielding film 52a in the thickness direction, the first light shielding film 52a and the first region 71 are on one side (first corner side) of the cell region 20a in plan view, the second light shielding film 52b and the second region 72 are on the other side (second corner side) of the cell region 20a in plan view, and the second region 72 is at a position overlapping the second light shielding film 52b in plan view. Since the photodetection device 1 has such a configuration, as illustrated in FIG. 4E, the main light beam L1 is deflected toward the second light shielding film 52b overlapping the second region 72 in plan view due to the refractive index difference between the first region 71 and the second region 72, and hardly reaches first light shielding film 52a. Therefore, an optical path length difference hardly occurs in the main light beam L1 incident on the cell region 20a, and as illustrated in FIG. 7, it is possible to suppress an increase in asymmetry of the incident angle characteristic of the output of the pixel 3, and it is possible to suppress an increase in the output of the pixel 3 at a specific incident angle. Therefore, this can suppress an increase in the difference in the shading amount between the one side of the angle-of-view end and the other side of the angle-of-view end. Then, deterioration of the captured image can be suppressed.

Furthermore, in the photodetection device 1 according to the first embodiment of the present technology, the charge holding unit MEM is at a position closer to one side (first corner side) of the cell region 20a in plan view, and the first light shielding film 52a and the first region 71 are at positions overlapping the charge holding unit MEM in plan view. As described above, the main light beam L1 is deflected toward the second light shielding film 52b, which is one of the first light shielding film 52a and the second light shielding film 52b and is at a position more distant from the charge holding unit MEM in both the thickness direction and the horizontal direction, so that the light is less likely to be incident on the charge holding unit MEM, and PLS can be suppressed.

Furthermore, in the photodetection device 1 according to the first embodiment of the present technology, the semiconductor layer 20 includes the plurality of cell region assemblies B1 each including the four cell regions 20a in two rows and two columns and arranged in the row direction and the column direction, the second corner of each of the four cell regions 20a constituting one cell region assembly B1 is a corner located close to the center of the cell region assembly B1, the first corner of each of the four cell regions 20a constituting one cell region assembly B1 is a corner located close to the corner of the cell region assembly B1, and the second regions 72 are collectively provided for each cell region assembly B1 and overlap all the second corners of each cell region assembly B1 in plan view. With such a configuration, the same effect can be obtained in each of the cell regions 20a of two rows and two columns arranged in the mirror target. Furthermore, by providing the second region 72 across the cell region 20a, the region of the second region 72 is widened, and the effect of deflecting light is further increased.

Note that, in the photodetection device 1 according to the first embodiment, a portion of the insulating layer 63 embedded between the second regions 72 is set as the first region 71 of the deflection layer 70, but the present technology is not limited thereto. The first region 71 may include a layer different from the insulating layer 63.

Furthermore, in the photodetection device 1 according to the first embodiment, the second regions 72 are collectively provided for each cell region assembly B1, but may be provided for each cell region 20a.

### Modifications of First Embodiment

In the description below, modifications of the first embodiment are explained.

### First Modification

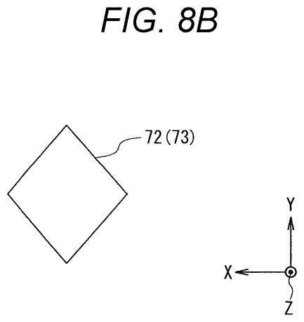

In the photodetection device 1 according to the first embodiment, the second region 72 (member 73) of the deflection layer 70 has a hexagonal shape in plan view, but the present technology is not limited thereto. The second region 72 (member 73) of the photodetection device 1 according to a first modification of the first embodiment may be circular in plan view as illustrated in FIG. 8A, or may be a rhombus in plan view as illustrated in FIG. 8B.

Effects similar to those of the photodetection device 1 according to the first embodiment described above can be achieved with the photodetection device 1 according to the first modification of the first embodiment.

### Second Modification

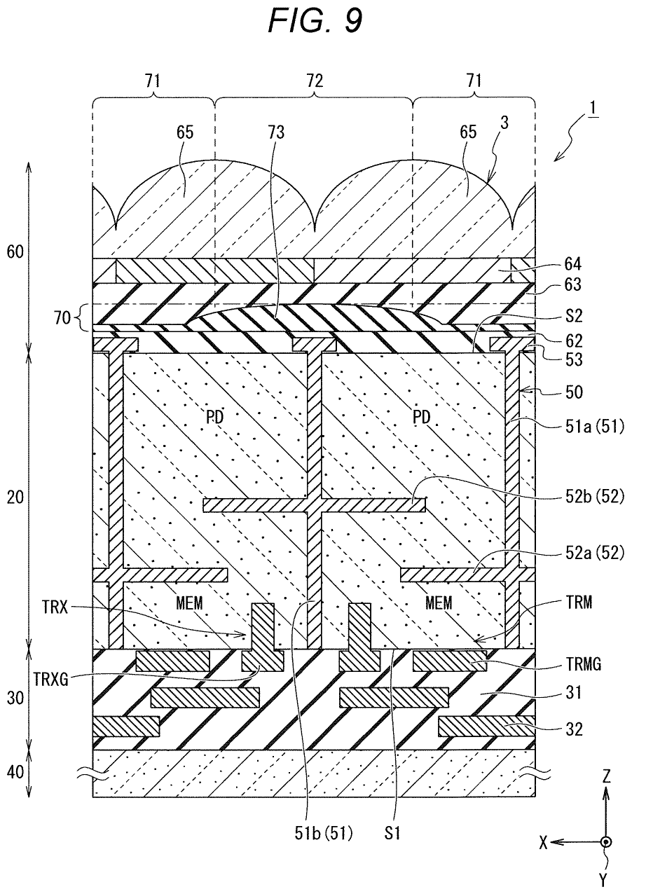

In the photodetection device 1 according to the first embodiment, the member 73 containing the second material is a plate-like member and has a substantially uniform thickness, but the present technology is not limited thereto. As illustrated in FIG. 9, the thickness of the member 73 of the photodetection device 1 according to a second modification of the first embodiment is not uniform. Furthermore, the first region 71 of the deflection layer 70 is a region mainly overlapping the first light shielding film 52a in plan view, and the second region 72 is a region mainly overlapping the second light shielding film 52b in plan view. Then, both the first region 71 and the second region 72 include both layers of the member 73 and the insulating layer 63, and the thickness of the member 73 in the second region 72 is thicker than the thickness of the member 73 in the first region 71.

Although not illustrated, the member 73 has a lens-shaped portion having the largest thickness at the center of the cell region assembly B1. Then, the thickness of the member 73 gradually decreases from the second region 72 toward the first region 71. In the present embodiment, the refractive index of the deflection layer 70 is changed by changing the thickness of the member 73. More specifically, by making the thickness of the member 73 in the first region 71 thinner than the thickness of the member 73 in the second region 72, the refractive index (first refractive index) of the first region 71 is made lower than the refractive index (second refractive index) of the second region 72. In other words, among the members 73 that gradually become thinner from the other side (second corner side) toward one side (first corner side) of the cell region 20a, the thinner side constitutes the first region 71, and the thicker side constitutes the second region 72. In a case where the thickness of the member 73 is thin, the optical path length of the main light beam L1 in the member 73 becomes short as compared with a case where the thickness is thick, and thus, the delay of the wavefront P becomes small. Note that a portion where the thickness of the member 73 is not uniform is formed over the plurality of pixels 3.

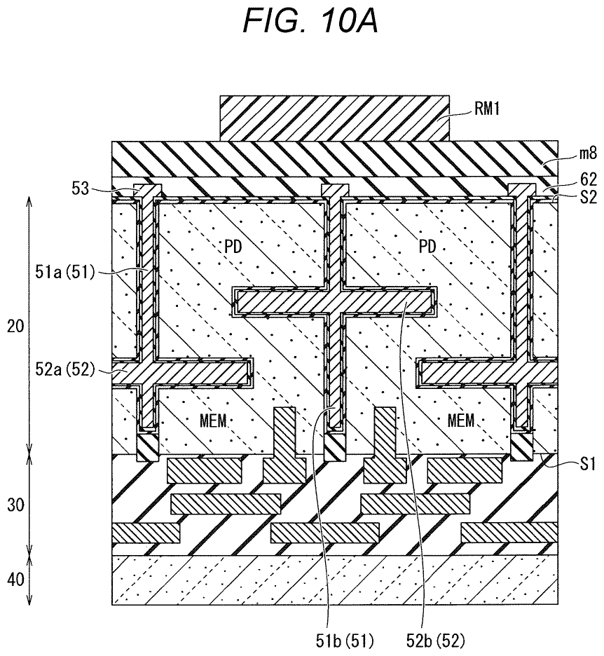

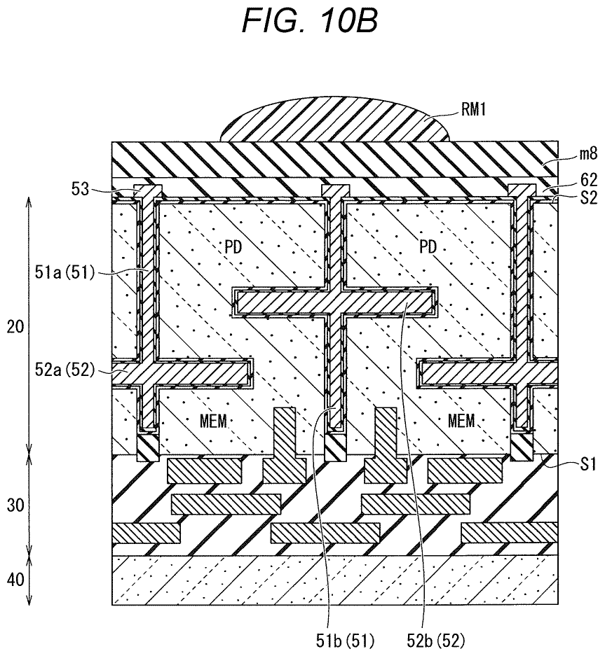

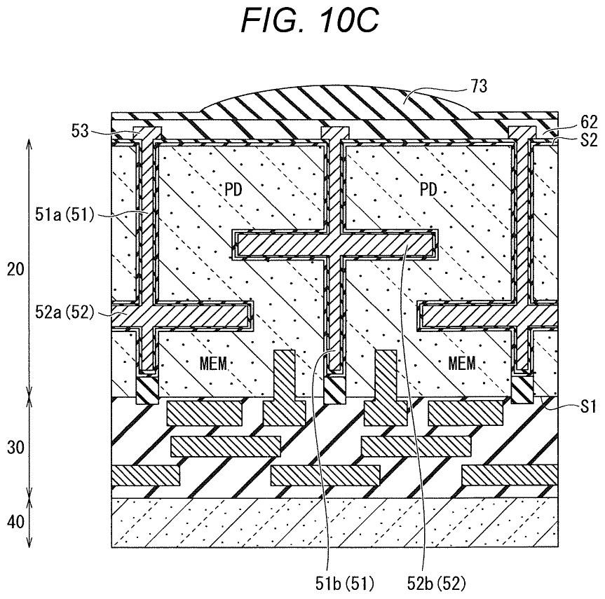

Hereinafter, with reference to FIGS. 10A to 10C, a method for manufacturing a photodetection device 1 according to the second modification of the first embodiment will be described focusing on portions different from those of the above-described first embodiment. First, among the processes described in the first embodiment, the processes up to the process shown in FIG. 5I are performed. Then, as illustrated in FIG. 10A, a resist pattern RM1 is formed on the exposed surface of the film m8 containing the second material. The resist pattern RM1 is formed at a position overlapping a portion of the member 73 desired to be left in a lens shape in plan view. Next, as illustrated in FIG. 10B, the resist pattern RM1 is reflowed by heat treatment or the like, and the thickness of the resist pattern RM1 is made thicker in a portion where it is desired to leave the film m8 thicker. Thereafter, the film m8 is etched using the resist pattern RM1 as a mask to obtain the member 73 illustrated in FIG. 10C. Note that, the resist pattern RM1 remaining after the etching is peeled off. Since the subsequent processes are similar to the processes described in the first embodiment, the description thereof will be omitted.

Effects similar to those of the photodetection device 1 according to the first embodiment described above can also be achieved with the photodetection device 1 according to the second modification of the first embodiment.

Furthermore, in the photodetection device 1 according to the second modification of the first embodiment, since the thickness of the member 73 gradually decreases from the center of the second region 72, that is, the cell region assembly B1 toward the first region 71, the member 73 can also function as a lens that collects light to the second region 72.

### Third Modification

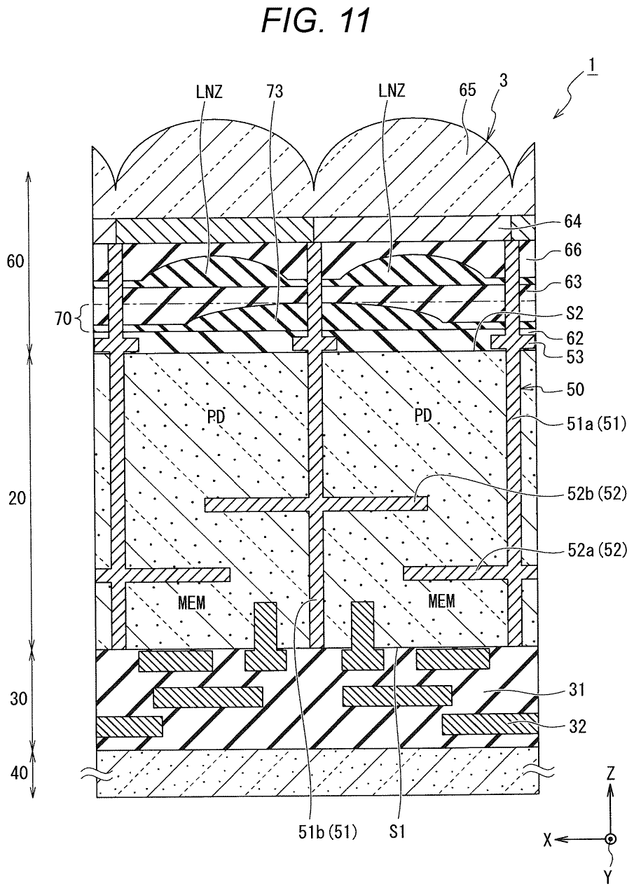

As illustrated in FIG. 11, a member 73 of a photodetection device 1 according to a third modification of the first embodiment includes an inner lens LNZ for each pixel 3. The inner lens LNZ is an on-chip lens, and is provided between the member 73 and the color filter 64. When the pixel 3 is highly distributed, light at a certain angle may be less likely to be incident on the semiconductor layer. When the inner lens LNZ is provided, it is possible to suppress light from hitting a partition wall that partitions pixels. Therefore, it is possible to suppress deterioration of oblique incidence characteristics.

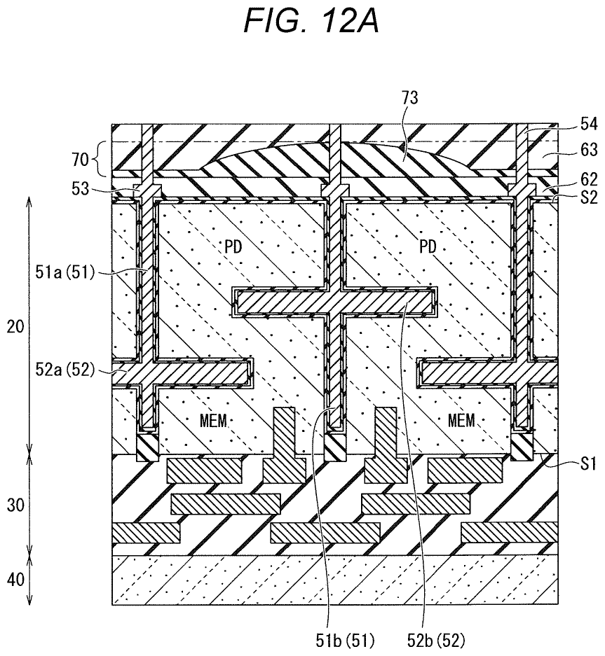

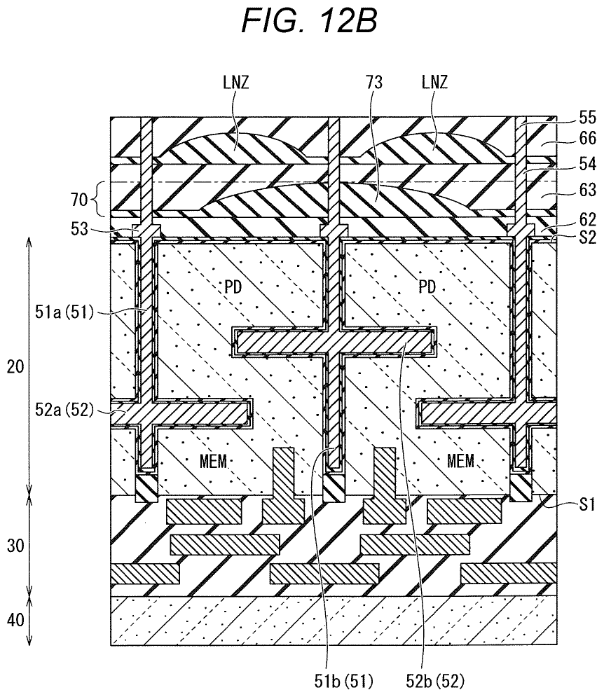

Hereinafter, with reference to FIGS. 12A and 12B, a method for manufacturing a photodetection device 1 according to the third modification of the first embodiment will be described focusing on portions different from those of the above-described second modification of the first embodiment. First, the insulating layer 63 containing a known material is stacked and planarized so as to cover the member 73 from the state of FIG. 10C described in the second modification of the first embodiment. Thereafter, as illustrated in FIG. 12A, a partition wall 54 that partitions between the pixels 3 is formed at a position overlapping the inter-pixel light-shielding film 53 in plan view using a known method.

Next, as illustrated in FIG. 12B, the inner lens LNZ is formed for each pixel 3 by using the same forming method as the member 73 described in the second modification of the first embodiment. Thereafter, an insulating layer 66 containing a known material is stacked and planarized. Thereafter, a partition wall 55 that partitions between the pixels 3 is formed at a position overlapping the partition wall 54 in plan view using a known method. Since the subsequent processes are as described above, the description thereof will be omitted.

Effects similar to those of the photodetection device 1 according to the first embodiment described above and the photodetection device 1 according to the second modification of the first embodiment described above can be achieved with the photodetection device 1 according to the third modification of the first embodiment.

Furthermore, in the photodetection device 1 according to the third modification of the first embodiment, it is possible to suppress deterioration of oblique incidence characteristics.

### Fourth Modification

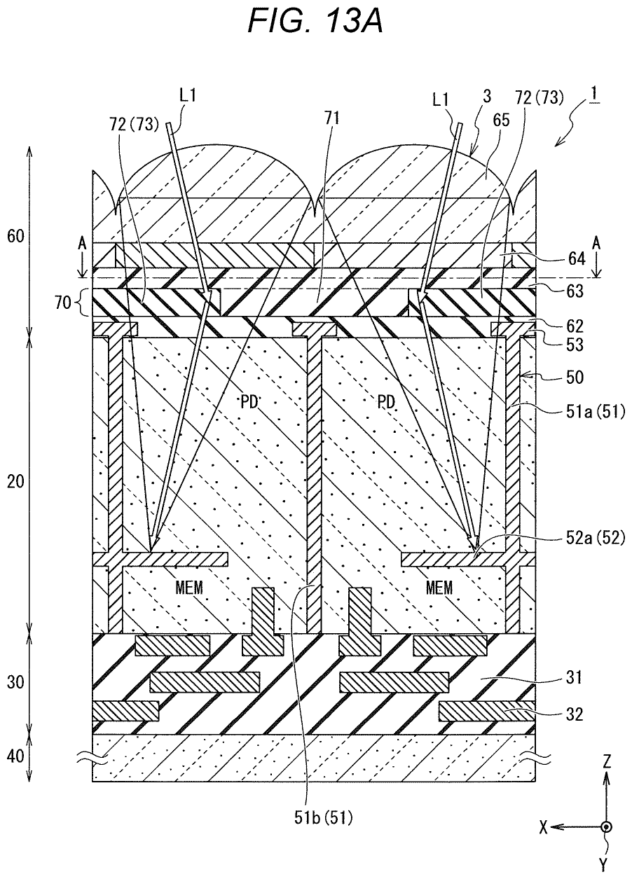

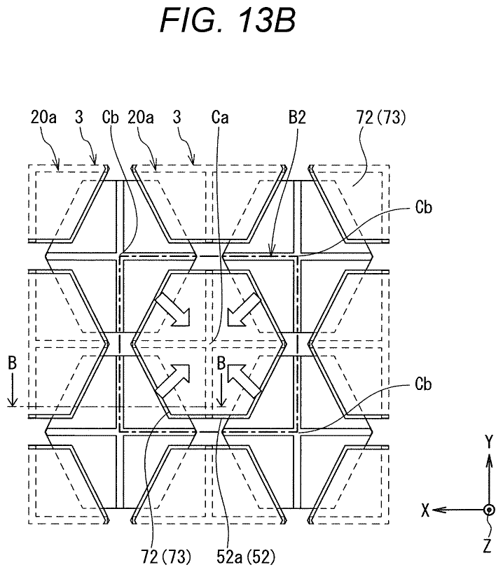

In the photodetection device 1 according to the first embodiment, the light shielding film 52 includes the two-layered light shielding film of the first light shielding film 52a and the second light shielding film 52b, but the present technology is not limited thereto. As illustrated in FIGS. 13A and 13B, the light shielding film 52 of the photodetection device 1 according to a fourth modification of the first embodiment includes only one layer film containing one light shielding material, more specifically, only the first light shielding film 52a. Furthermore, in the photodetection device 1 according to the first embodiment, the second region 72 of the deflection layer 70 is on the other side of the cell region 20a, but is on one side of the cell region 20a of the second region 72 of the photodetection device 1 according to the fourth modification of the first embodiment. Note that FIG. 13A illustrates a cross-sectional configuration of the pixel 3 when viewed in a cross-sectional view taken along line B-B in FIG. 13.

As illustrated in FIG. 13B, in the present modification, one cell region assembly B2 is constituted by four cell regions 20a in two rows and two columns with the cross center Ca at the center. A first corner is located near the center of the cell region assembly B2, and a second corner is located near the corner. Then, the second region 72 is provided collectively for each cell region assembly B2, and overlaps all the first corners for each cell region assembly B2 in plan view.

In plan view, the first light shielding film 52a and the second region 72 of the deflection layer 70 are on one side of the cell region 20a, more specifically, on the first corner side, and the first region 71 of the deflection layer 70 is on the other side of the cell region 20a, more specifically, on the second corner side. Furthermore, as in the case of the first embodiment, the charge holding unit MEM is at a position closer to one side of the cell region 20a in plan view. Then, the first light shielding film 52a and the second region 72 are at positions overlapping the charge holding unit MEM in plan view.

As illustrated in FIG. 13A, since the second region 72 is at a position overlapping the first light shielding film 52a in plan view, the main light beam L1 is deflected in each cell region 20a in a direction in which the first light shielding film 52a exists in plan view. More specifically, the main light beam L1 is deflected toward the first light shielding film 52a overlapping the charge holding unit MEM in plan view in each cell region 20a. That is, the main light beam L1 is deflected toward one side (first corner side) of one side and the other side of cell region 20a.

Effects similar to those of the photodetection device 1 according to the first embodiment described above can be obtained with the photodetection device 1 according to the fourth modification of the first embodiment as well.

Furthermore, in the photodetection device 1 according to the fourth modification of the first embodiment, since the main light beam L1 is deflected toward the first light shielding film 52a, the optical path length is longer than that in the case of the first embodiment. Therefore, deterioration in sensitivity can be suppressed, and sensitivity can be improved.

Furthermore, in the photodetection device 1 according to the fourth modification of the first embodiment, since the main light beam L1 is blocked by the first light shielding film 52a, it becomes difficult for the main light beam L1 to be incident on the charge holding unit MEM.

### Second Embodiment

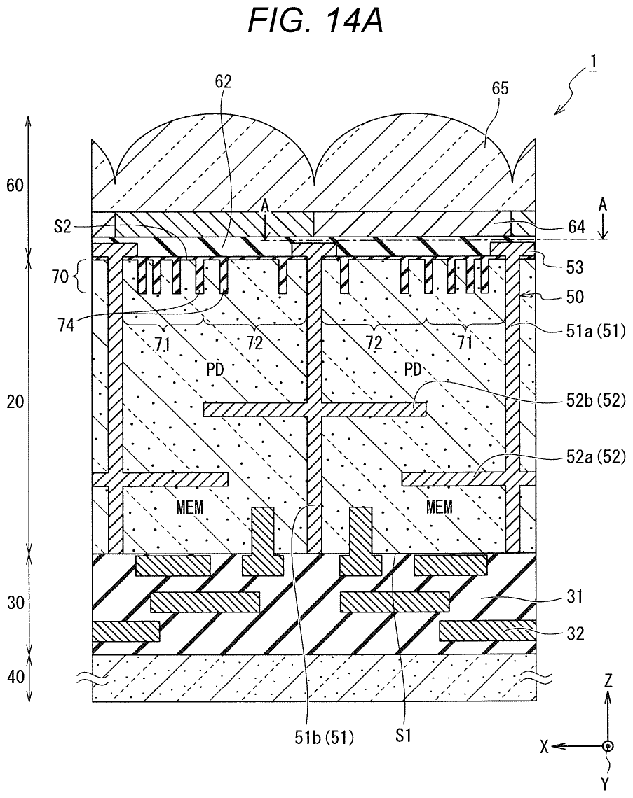

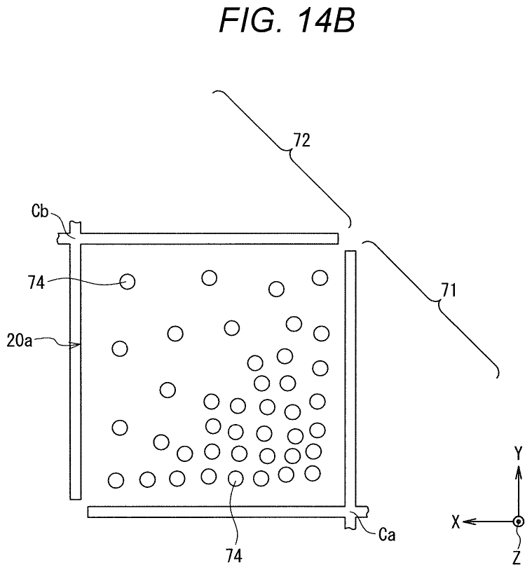

A second embodiment of the present technology illustrated in FIGS. 14A and 14B is described below. The photodetection device 1 according to the second embodiment is different from the photodetection device 1 according to the first embodiment described above in that the deflection layer 70 is provided in a portion of the cell region 20a on the second surface S2 (light incident surface) side, and other configurations of the photodetection device 1 are basically similar to those of the photodetection device 1 according to the first embodiment described above. Note that the components already described are denoted by the same reference signs, and explanation of them is not made herein.

As illustrated in FIG. 14A, the deflection layer 70 is provided in a portion of the cell region 20a on the second surface S2 side, and includes a plurality of columnar bodies 74 extending from the second surface S2 in the thickness direction of the semiconductor layer 20 for each cell region 20a. The columnar body 74 is an on-chip pillar, and the dimension in the Z direction is not limited thereto, but is, for example, 0.8 μm. The refractive index of the material constituting the columnar body 74 is different from the refractive index of the semiconductor layer 20. More specifically, the refractive index of the material constituting the columnar body 74 is lower than the refractive index of the semiconductor layer 20. Then, as illustrated in FIG. 14B, the density of the columnar bodies 74 provided in the first region 71 is different from the density of the columnar bodies 74 provided in the second region 72. More specifically, the density of the columnar bodies 74 provided in the first region 71 is higher than the density of the columnar bodies 74 provided in the second region 72. In other words, a region having a low refractive index (a region having a high density of the columnar bodies 74) is set as the first region, and a region having a high refractive index (a region having a low density of the columnar bodies 74) is set as the second region. In the present embodiment, the refractive index of the deflection layer 70 is changed by changing the density of the columnar bodies 74 between the first region 71 and the second region 72. More specifically, by making the density of the columnar bodies 74 in the first region 71 higher than the density of the columnar bodies 74 in the second region 72, the refractive index (first refractive index) of the first region 71 is made lower than the refractive index (second refractive index) of the second region 72. In other words, the refractive index is adjusted by the ratio of the area of the material constituting the semiconductor layer 20 and the material constituting the columnar body 74 in plan view. In the present embodiment, in the case of the present embodiment, a region having a large area of the semiconductor layer 20 is configured to have a high refractive index. With such a configuration, the main light beam L1 incident on the pixel 3 is deflected toward the second light shielding film 52b located on the other side (second corner side) of the cell region 20a. Note that, as illustrated in FIG. 14B, in plan view of the cell region 20a, the density of the columnar bodies 74 may be gradually increased from the other side which is the cross center Ca side to the one side which is the cross center Cb side.

A material constituting the columnar body 74 is a first material, and a material constituting the semiconductor layer 20 is a second material. Examples of the first material include, but are not limited to, a substance such as silicon oxide (SiO₂). Furthermore, the second material is not limited thereto, and examples thereof include a substance such as silicon.

### <<Method for Manufacturing Photodetection Device>>

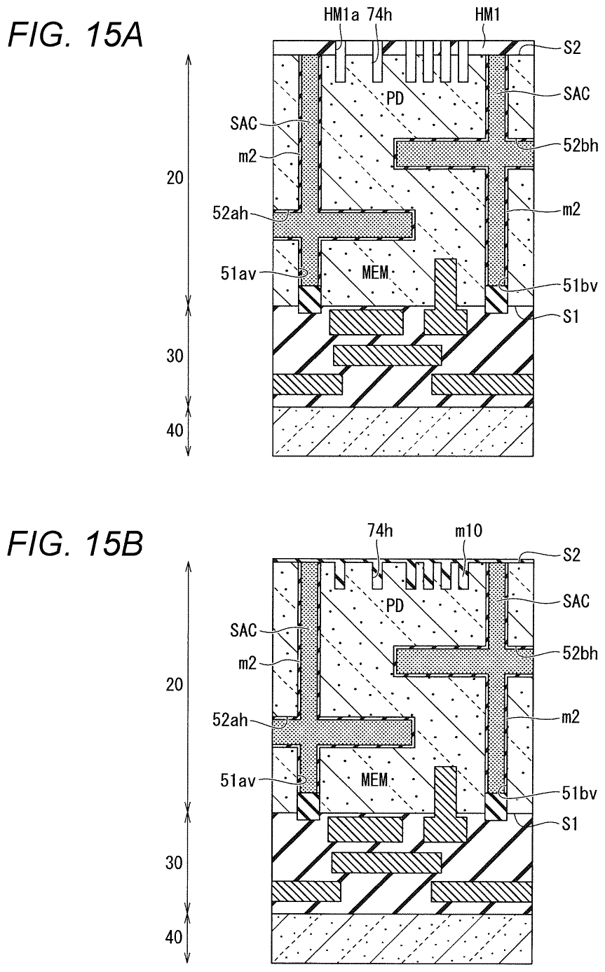

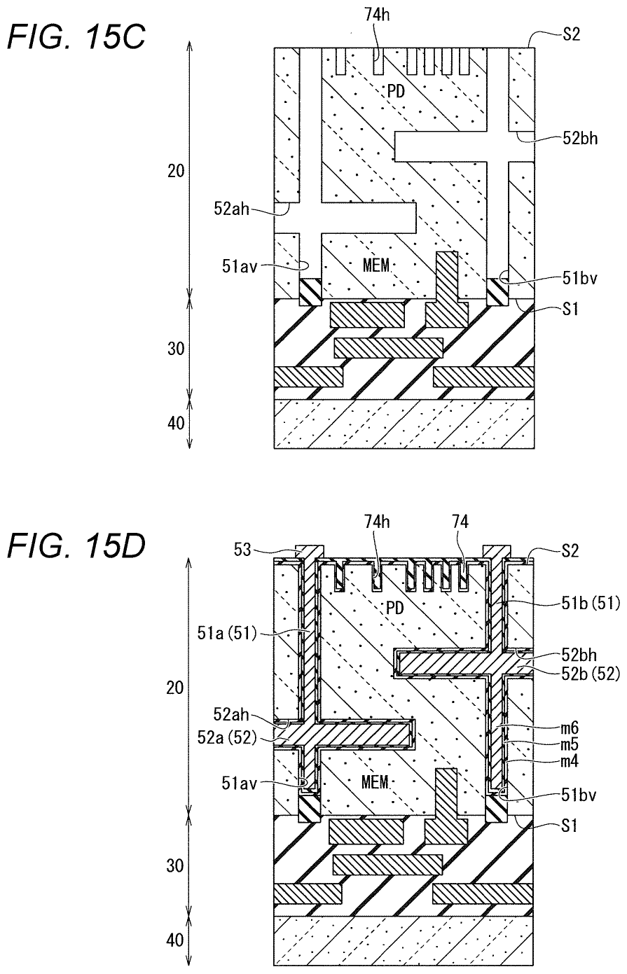

Hereinafter, with reference to FIGS. 15A to 15D, a method for manufacturing the photodetection device 1 will be described focusing on portions different from those of the above-described first embodiment. First, among the processes described in the first embodiment, the processes up to the process shown in FIG. 5F are performed. Then, as illustrated in FIG. 15A, a hard mask HM1 having an opening HM1a is formed on the second surface S2 of the semiconductor layer 20 by using a known lithography technique and etching technique. Then, a portion of the semiconductor layer 20 exposed from the opening HM1a is etched using a known etching technique to form a plurality of holes 74h for embedding the columnar bodies 74. Thereafter, the hard mask HM1 is removed.

Next, as illustrated in FIG. 15B, an insulation film m10 is deposited on the exposed surface of the semiconductor layer 20 using a known film forming technique such as an ALD method, and the inside of the hole 74h is filled with the insulation film m10. Thereafter, although not partially illustrated, as illustrated in FIG. 15C, the sacrificial film SAC is removed by wet etching using an alkaline solution through an opening of a hard mask (not illustrated), and then the hard mask (not illustrated) and the insulation film m10 are removed.

Then, as illustrated in FIG. 15D, the pinning layer m4 and the insulation film m5 are sequentially stacked in this order on the exposed surface in the hole 74h and the exposed surfaces of the vertical grooves 51av and 51bv and the lateral grooves 52ah and 52bh. The columnar body 74 is formed in the hole 74h by filling the inside of the hole 74h with the insulation film m5. The insulation film m5 contains a material constituting the columnar body 74. Thereafter, as in the case of the first embodiment, the cavity portions in the vertical grooves 51av and 51bv and the lateral grooves 52ah and 52bh are filled with the light shielding material m6. Since the subsequent processes are similar to the case of the first embodiment, the description thereof will be omitted.

### Principal Effects of Second Embodiment

Effects similar to those of the photodetection device 1 according to the first embodiment described above can also be achieved with the photodetection device 1 according to the second embodiment.

Note that, in the photodetection device 1 according to the second embodiment, the refractive index of the material constituting the columnar body 74 is lower than the refractive index of the semiconductor layer 20, but the refractive index of the material constituting the columnar body 74 may be higher than the refractive index of the semiconductor layer 20. In this case, since a region having a large area of the semiconductor layer 20 in plan view has a low refractive index, the density of the columnar bodies 74 in the first region 71 is made lower than the density of the columnar bodies 74 in the second region 72, so that the refractive index (first refractive index) of the first region 71 can be made lower than the refractive index (second refractive index) of the second region 72.

### Modifications of Second Embodiment

In the description below, modifications of the second embodiment are explained.

### First Modification

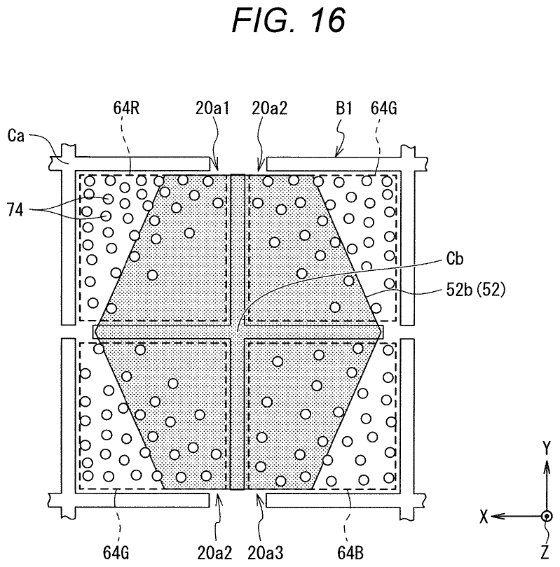

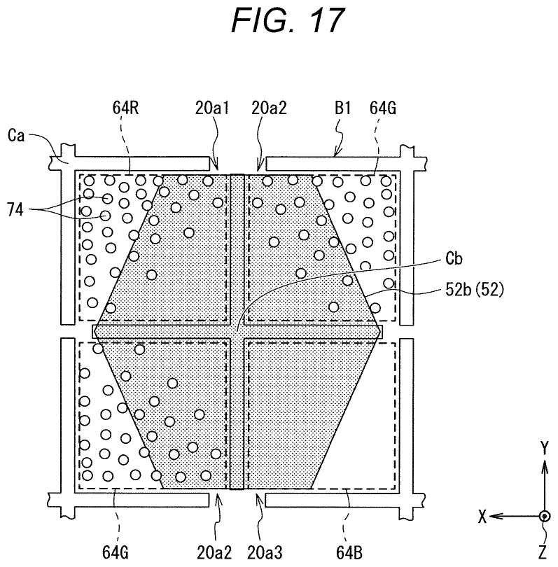

In the photodetection device 1 according to a first modification of the second embodiment, as illustrated in FIG. 16, the refractive index distribution of the deflection layer 70 is different for each color mainly transmitted by the color filter 64.

First, before describing the present modification, a difference in the incident angle characteristic of the output of the pixel 3 depending on the color in a case where the deflection layer 70 is not provided will be described with reference to FIG. 6B. The asymmetry of the incident angle characteristic of the output of the pixel 3 becomes more remarkable as the wavelength of light is longer. Therefore, light having a long wavelength such as red light may reach the first light shielding film 52a more than green light and blue light having a short wavelength, and the amount of light having a long optical path may increase. Then, as a result, the color ratio may fluctuate. Therefore, it is desirable to make the degree of deflection by the deflection layer 70 larger for light having a long wavelength than for light having a shorter wavelength. Furthermore, in a case where the deflection layer 70 having the same refractive index configuration is applied to light of different colors, light having a shorter wavelength is deflected more than light having a longer wavelength. That is, in a case where the deflection layer 70 having the same refractive index configuration is applied, the deflection amount of light having a long wavelength such as red light is smaller than that of light having a short wavelength such as green light and blue light. Therefore, in the present modification, by changing the refractive index difference between the first region 71 and the second region 72 for each color, an increase in the fluctuation of the color ratio is suppressed. More specifically, by providing a larger refractive index difference between the first region 71 and the second region 72 for light having a longer wavelength such as red light, an increase in the fluctuation of the color ratio is suppressed.

The cell region 20a includes a first cell region 20a1, a second cell region 20a2, and a third cell region 20a3, and the color filter 64 includes a first filter 64R for first color light provided for the first cell region 20a1, a second filter 64G for second color light provided for the second cell region 20a2 and having a wavelength shorter than that of the first color light, and a third filter 64B for third color light provided for the third cell region 20a3 and having a wavelength shorter than that of the second color light. Note that, for example, in the case of the Bayer array, the first color light is red light, the second color light is green light, and the third color light is blue light. Then, the refractive index difference between the first region 71 and the second region 72 of the deflection layer 70 provided in the first cell region 20a1 is larger than the refractive index difference between the first region 71 and the second region 72 of the deflection layer 70 provided in the second cell region 20a2, and the refractive index difference between the first region 71 and the second region 72 of the deflection layer 70 provided in the second cell region 20a2 is larger than the refractive index difference between the first region 71 and the second region 72 of the deflection layer 70 provided in the third cell region 20a3. That is, the refractive index difference between the first region 71 and the second region 72 is increased as the wavelength of light is longer. Therefore, the degree of deflection toward the second light shielding film 52b can be increased as the wavelength of light is longer.

Effects similar to those of the photodetection device 1 according to the second embodiment described above can also be achieved with the photodetection device 1 according to the first modification of the second embodiment.

Furthermore, in the photodetection device 1 according to the first modification of the second embodiment, since the refractive index difference between the first region 71 and the second region 72 is increased as the wavelength of light is longer, it is possible to suppress an increase in the fluctuation of the color ratio.

### Second Modification

In the photodetection device 1 according to a second modification of the second embodiment, as illustrated in FIG. 17, the deflection layer 70 is not provided for the third cell region 20a3 for the third color light in which the wavelength of the incident main light beam is the shortest among the first cell region 20a1 to the third cell region 20a3, and the deflection layer 70 is provided only for the first cell region 20a1 for the first color light and the second cell region 20a2 for the second color light. The third color light having the shortest wavelength has the smallest influence on the asymmetry of the incident angle characteristic of the output of the pixel 3 among the first color light to the third color light. Therefore, the deflection layer 70 is omitted with respect to the third cell region 20a3 for the third color light. Note that, in the example illustrated in FIG. 17, the refractive index difference between the first region 71 and the second region 72 of the deflection layer 70 provided in the first cell region 20a1 is larger than the refractive index difference between the first region 71 and the second region 72 of the deflection layer 70 provided in the second cell region 20a2. However, the refractive index difference between the first region 71 and the second region 72 of the deflection layer 70 provided in the first cell region 20a1 and the refractive index difference between the first region 71 and the second region 72 of the deflection layer 70 provided in the second cell region 20a2 may be the same.

Effects similar to those of the photodetection device 1 according to the second embodiment described above and the photodetection device 1 according to the first modification of the second embodiment described above can be achieved with the photodetection device 1 according to the second modification of the second embodiment. Furthermore, in the photodetection device 1 according to the second modification of the second embodiment, since the deflection layer 70 can be omitted with respect to the third cell region 20a3 for the third color light, a design load and a manufacturing cost can be suppressed.

### Third Modification

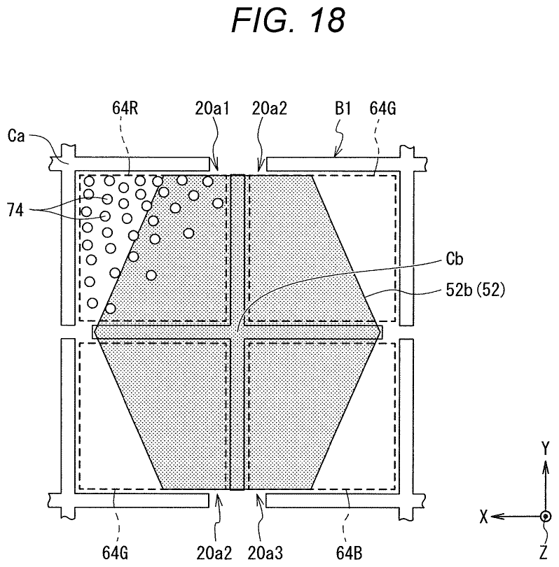

In the photodetection device 1 according to a third modification of the second embodiment, as illustrated in FIG. 18, the deflection layer 70 is provided only in the first cell region 20a1 for the first color light among the first cell region 20a1 to the third cell region 20a3.

The first color light having the longest wavelength has the largest influence on the asymmetry of the incident angle characteristic of the output of the pixel 3 among the first color light to the third color light. Therefore, the deflection layer 70 is provided only for the first cell region 20a1 for the first color light having the largest influence.

Effects similar to those of the photodetection device 1 according to the second embodiment described above and the photodetection device 1 according to the first modification of the second embodiment described above can be achieved with the photodetection device 1 according to the third modification of the second embodiment. Furthermore, in the photodetection device 1 according to the third modification of the second embodiment, since the deflection layer 70 is provided only for the first cell region 20a1 for the first color light, a design load and a manufacturing cost can be suppressed.

### Third Embodiment

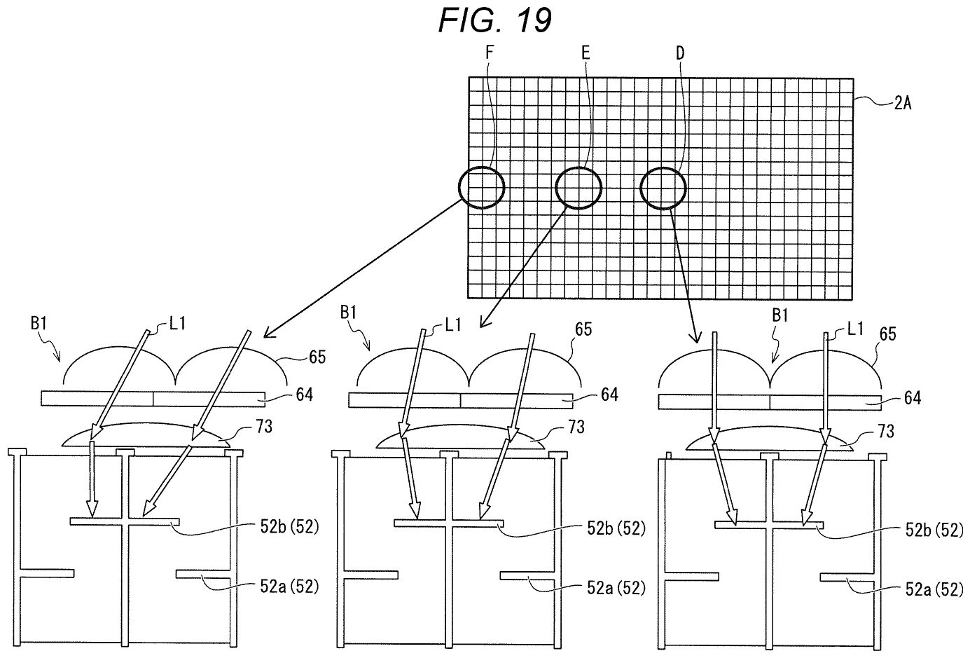

A third embodiment of the present technology illustrated in FIG. 19 is described below. The photodetection device 1 according to the third embodiment is different from the photodetection device 1 according to the first embodiment described above in that pupil correction is performed, and other configurations of the photodetection device 1 are basically similar to those of the photodetection device 1 according to the first embodiment described above. Note that the components already described are denoted by the same reference signs, and explanation of them is not made herein. Note that, in the present embodiment, a case where the member 73 has a lens shape as illustrated in the drawing will be described. Furthermore, in FIG. 19, reference signs “71” and “72” of the first region 71 and the second region 72 are omitted, but the second region 72 is assumed to be in a portion where the thickness of the member 73 is thick.

As illustrated in FIG. 19, in a case where the pixel region 2A is viewed in plan view, a region D is at the central portion of the pixel region 2A, that is, at the center of the image height. On the other hand, a region F is located closer to the edge of the pixel region 2A than the region D, that is, at a position where the image height is higher. A region E is located closer to the edge than the region D and closer to the central portion than the region F. In the present embodiment, the regions E and F will be described as examples of regions located closer to the edge than the central portion of the pixel region 2A.

In the region D located at the center of the image height, the main light beam L1 is incident at an angle close to perpendicular to the pixel 3. On the other hand, as the image height increases, the main light beam L1 is incident on the pixel 3 more obliquely. In the regions E and F, the main light beam L1 is obliquely incident on the pixel 3. Furthermore, in the region F, the main light beam L1 is incident on the pixel 3 more obliquely than in the region E.

In the cell region assembly B1 located in the region D, the center of the member 73 is at the center of the cell region assembly B1 in plan view. On the other hand, in the cell region assembly B1 located in the regions E and F, the center of the member 73 is located closer to the central portion of the pixel region 2A than the center of the cell region assembly B1 in plan view. Moreover, in the cell region assembly B1 located in the region F, the center of the member 73 is located closer to the central portion of the pixel region 2A in plan view than the cell region assembly B1 located in the region E. The pupil correction is performed by arranging the member 73 at a position where the image height is high as described above. Note that, similarly to the member 73, the color filter 64 and the microlens 65 are also arranged at positions closer to the central portion of the pixel region 2A than the center of the cell region assembly B1 according to the image height position. Therefore, the main light beam L1 can be deflected toward the second light shielding film 52b regardless of the image height position of the pixel region 2A.

Effects similar to those of the photodetection device 1 according to the first embodiment described above can also be achieved with the photodetection device 1 according to the third embodiment.

Furthermore, in the photodetection device 1 according to the third embodiment, even in the pixel 3 having a high image height, the main light beam L1 can be deflected toward the second light shielding film 52b by arranging the second region 72 closer to the central portion of the pixel region 2A than to the center of the cell region assembly B1.

Note that, the case where the cell region assembly is the cell region assembly B1 has been described in the photodetection device 1 of the third embodiment, but the cell region assembly may be the cell region assembly B2.

### Fourth Embodiment

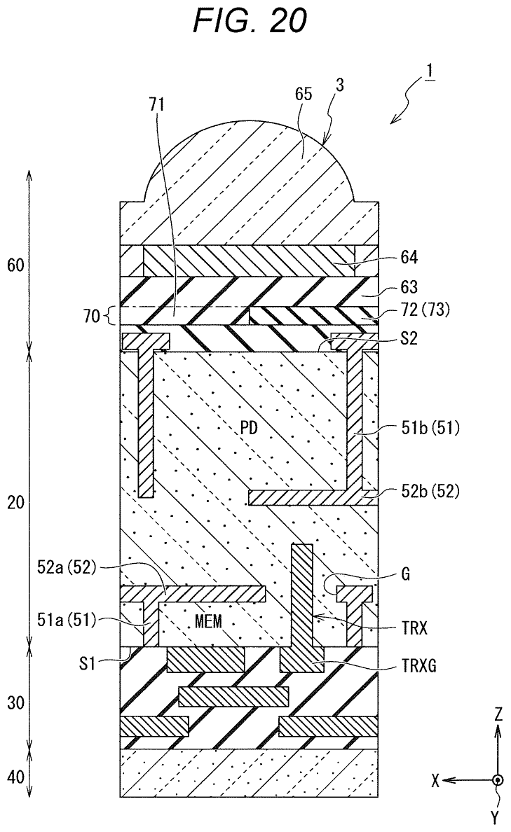

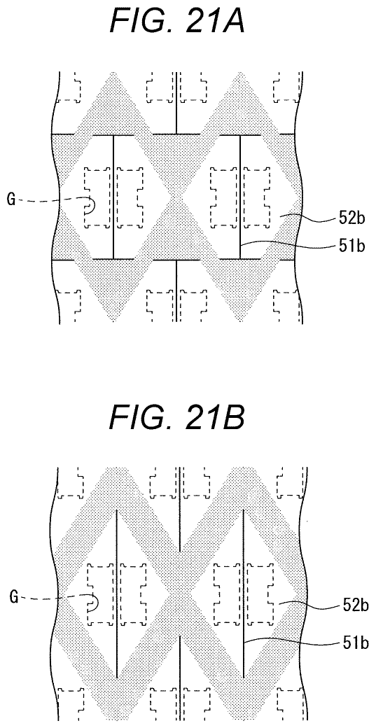

A fourth embodiment of the present technology illustrated in FIGS. 20, 21A, and 21B will be described below. A photodetection device 1 according to the fourth embodiment differs from the photodetection device 1 according to the first embodiment described above in the configuration of the light shielding unit 50, and the other aspects of the configuration of the photodetection device 1 are basically similar to those of the photodetection device 1 according to the first embodiment described above. Note that the components already described are denoted by the same reference signs, and explanation of them is not made herein.

As illustrated in FIG. 20, the first partition wall 51a is provided from the first surface S1 side and does not reach the second surface S2. Then, the second partition wall 51b is provided from the second surface S2 side and does not reach the first surface S1. Furthermore, the vertical gate electrode TRXG protrudes from an opening G provided in the first light shielding film 52a. Note that, in plan view, the second partition wall 51b may have an I-shaped pattern as illustrated in FIG. 21A or a 1-shaped pattern as illustrated in FIG. 21B.

Effects similar to those of the photodetection device 1 according to the first embodiment described above can also be achieved with the photodetection device 1 according to the fourth embodiment.

### Fifth Embodiment

### <1. Example Application to Electronic Apparatus>

Next, an electronic apparatus 100 of an application example illustrated in FIG. 22 will be described. The electronic apparatus 100 includes a solid-state imaging device 101, an optical lens 102, a shutter device 103, a drive circuit 104, and a signal processing circuit 105. The electronic apparatus 100 is not limited to this, but is an electronic apparatus such as a camera, for example. Furthermore, the electronic apparatus 100 includes the photodetection device 1 described above as the solid-state imaging device 101.

The optical lens (optical system) 102 forms an image of image light (incident light 106) from the subject on the imaging surface of the solid-state imaging device 101. Therefore, signal charges are accumulated in the solid-state imaging device 101 over a certain period of time. The shutter device 103 controls a light irradiation period and a light shielding period for the solid-state imaging device 101. The drive circuit 104 supplies a drive signal for controlling a transfer operation of the solid-state imaging device 101 and a shutter operation of the shutter device 103. In accordance with a drive signal (a timing signal) supplied from the drive circuit 104, the solid-state imaging device 101 performs signal transfer. The signal processing circuit 105 performs various kinds of signal processing on a signal (pixel signal) that is output from the solid-state imaging device 101. A video signal subjected to the signal processing is stored into a storage medium such as a memory, or is output to a monitor.

With such a configuration, in the electronic apparatus 100, it is possible to suppress an increase in asymmetry of the incident angle characteristic of the output of the pixel 3 in the solid-state imaging device 101, and thus, it is possible to improve the image quality of the video signal.

Note that the electronic apparatus 100 is not necessarily a camera, and may be some other electronic apparatus. For example, the electronic apparatus may be an imaging device such as a camera module for a mobile device such as a mobile phone.

Furthermore, the electronic apparatus 100 can include, as the solid-state imaging device 101, the photodetection device 1 according to any one of the first to fourth embodiments and the modifications of these embodiments, or the photodetection device 1 according to a combination of at least two of the first to fourth embodiments and the modifications of these embodiments.

### <2. Example Application to Mobile Structure>

The technology according to the present disclosure (the present technology) can be applied to various products. For example, the technology of the present disclosure may be implemented as a device mounted on any kind of mobile structure such as an automobile, an electric vehicle, a hybrid electric vehicle, a motorcycle, a bicycle, a personal mobility, an airplane, a drone, a ship, a robot, and the like.

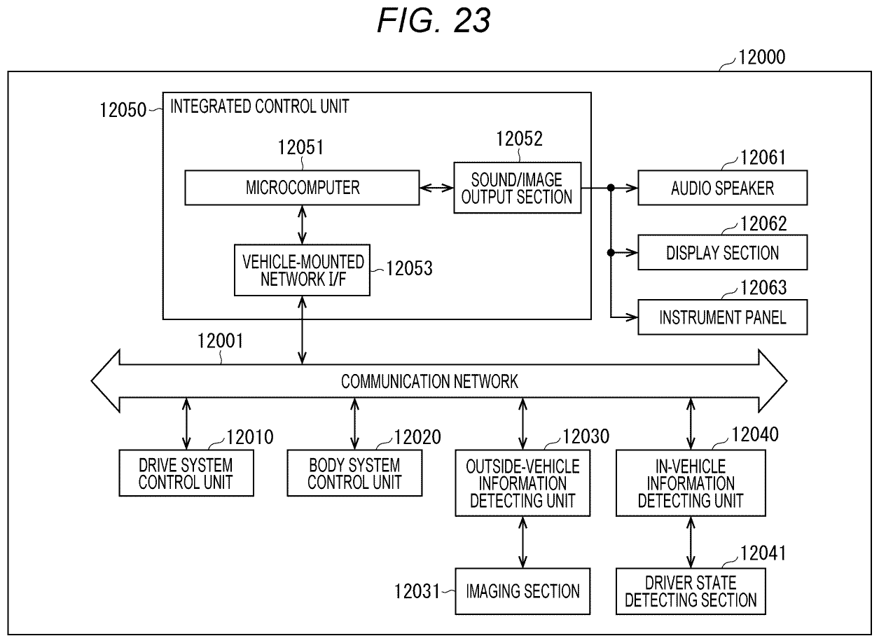

FIG. 23 is a block diagram illustrating a schematic configuration example of a vehicle control system which is an example of a mobile body control system to which the technology of the present disclosure can be applied.

The vehicle control system 12000 includes a plurality of electronic control units connected to each other via a communication network 12001. In the example illustrated in FIG. 23, the vehicle control system 12000 includes a driving system control unit 12010, a body system control unit 12020, an outside-vehicle information detecting unit 12030, an in-vehicle information detecting unit 12040, and an integrated control unit 12050. Furthermore, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

Furthermore, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 23, an audio speaker 12061, a display section 12062, and an instrument panel 12063 are illustrated as the output device. The display section 12062 may, for example, include at least one of an on-board display and a head-up display.

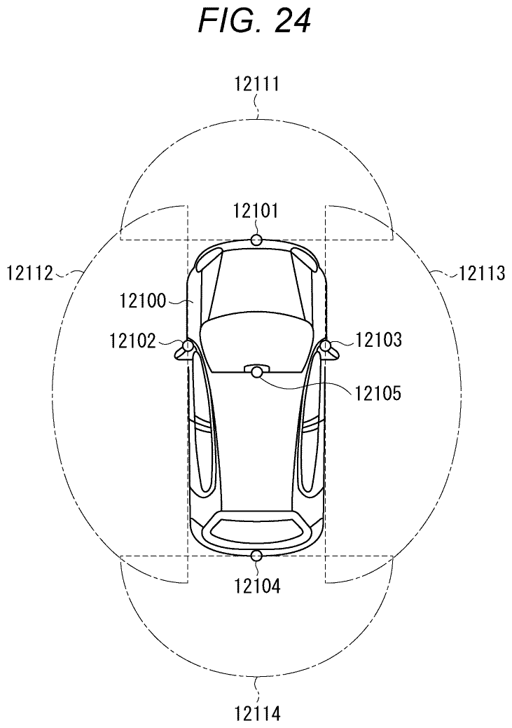

FIG. 24 is a view illustrating an example of the installation position of the imaging section 12031.

In FIG. 24, a vehicle 12100 includes imaging sections 12101, 12102, 12103, 12104, and 12105, as the imaging section 12031.

The imaging sections 12101, 12102, 12103, 12104, 12105 are provided, for example, at positions such as a front nose, a sideview mirror, a rear bumper, a back door, and an upper portion of a windshield in the interior of a vehicle 12100. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The forward images obtained by the imaging sections 12101 and 12105 are used mainly to detect a preceding vehicle, a pedestrian, an obstacle, a traffic signal, a traffic sign, a lane, or the like.

Note that FIG. 24 illustrates an example of imaging ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

An example of the vehicle control system to which the technology according to the present disclosure can be applied has been described above. The technology of the present disclosure can be applied to the imaging section 12031 among the configurations described above. Specifically, the photodetection device 1 described in the above-described embodiments and modifications can be applied to the imaging section 12031. By applying the technology of the present disclosure to the imaging section 12031, a more easily viewable captured image can be obtained, by which fatigue of the driver can be reduced.

### <3. Example Application to Endoscopic Surgery System>

The technology according to the present disclosure (the present technology) can be applied to various products. For example, the technology according to the present disclosure may be applied to an endoscopic surgery system.

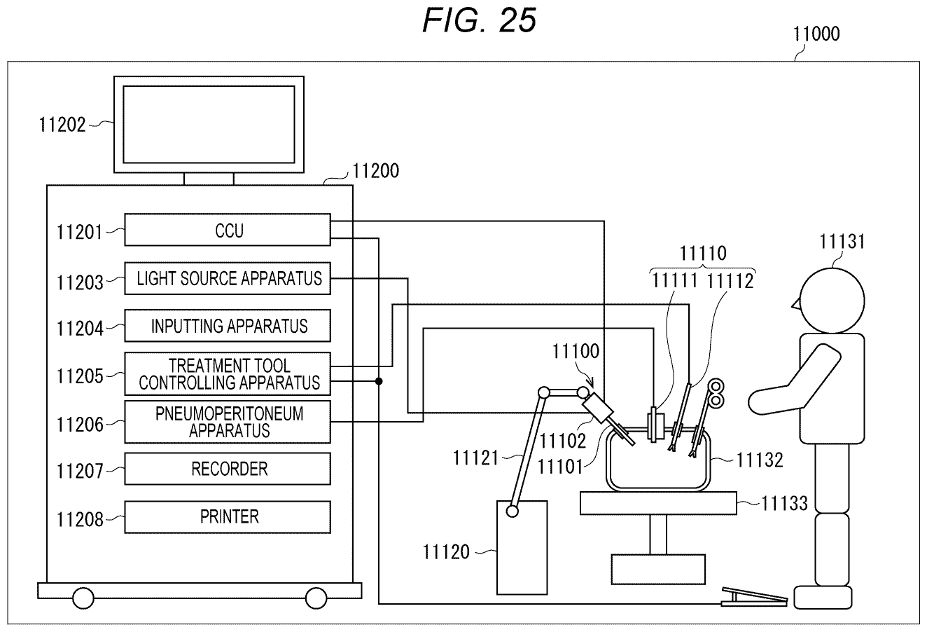

FIG. 25 is a diagram illustrating an example of a schematic configuration of an endoscopic surgery system to which the technology according to the present disclosure (present technology) can be applied.

In FIG. 25, a state is illustrated in which a surgeon (medical doctor) 11131 is using an endoscopic surgery system 11000 to perform surgery for a patient 11132 on a patient bed 11133. As depicted, the endoscopic surgery system 11000 includes an endoscope 11100, other surgical tools 11110 such as a pneumoperitoneum tube 11111 and an energy device 11112, a supporting arm apparatus 11120 which supports the endoscope 11100 thereon, and a cart 11200 on which various apparatus for endoscopic surgery are mounted.

The endoscope 11100 includes a lens barrel 11101 having a region of a predetermined length from a distal end thereof to be inserted into a body cavity of the patient 11132, and a camera head 11102 connected to a proximal end of the lens barrel 11101. In the example depicted, the endoscope 11100 is depicted which includes as a rigid endoscope having the lens barrel 11101 of the hard type. However, the endoscope 11100 may otherwise be included as a flexible endoscope having the lens barrel 11101 of the flexible type.

The lens barrel 11101 has, at a distal end thereof, an opening in which an objective lens is fitted. A light source apparatus 11203 is connected to the endoscope 11100 such that light generated by the light source apparatus 11203 is introduced to a distal end of the lens barrel 11101 by a light guide extending in the inside of the lens barrel 11101 and is irradiated toward an observation target in a body cavity of the patient 11132 through the objective lens. It is to be noted that the endoscope 11100 may be a forward-viewing endoscope or may be an oblique-viewing endoscope or a side-viewing endoscope.

An optical system and an image pickup element are provided in the inside of the camera head 11102 such that reflected light (observation light) from the observation target is condensed on the image pickup element by the optical system. The observation light is photo-electrically converted by the image pickup element to generate an electric signal corresponding to the observation light, namely, an image signal corresponding to an observation image. The image signal is transmitted as RAW data to a CCU 11201.

The CCU 11201 includes a central processing unit (CPU), a graphics processing unit (GPU) or the like and integrally controls operation of the endoscope 11100 and a display apparatus 11202. Further, the CCU 11201 receives an image signal from the camera head 11102 and performs, for the image signal, various image processes for displaying an image based on the image signal such as, for example, a development process (demosaic process).

The display apparatus 11202 displays thereon an image based on an image signal, for which the image processes have been performed by the CCU 11201, under the control of the CCU 11201. The light source apparatus 11203 includes a light source such as a light emitting diode (LED), for example, and supplies irradiation light for imaging a surgical region to the endoscope 11100.

An inputting apparatus 11204 is an input interface for the endoscopic surgery system 11000. A user can perform inputting of various kinds of information or instruction inputting to the endoscopic surgery system 11000 through the inputting apparatus 11204. For example, the user would input an instruction or a like to change an image pickup condition (type of irradiation light, magnification, focal distance or the like) by the endoscope 11100.

A treatment tool controlling apparatus 11205 controls driving of the energy device 11112 for cautery or incision of a tissue, sealing of a blood vessel or the like. A pneumoperitoneum apparatus 11206 feeds gas into a body cavity of the patient 11132 through the pneumoperitoneum tube 11111 to inflate the body cavity in order to secure the field of view of the endoscope 11100 and secure the working space for the surgeon. A recorder 11207 is an apparatus capable of recording various kinds of information relating to surgery. A printer 11208 is an apparatus capable of printing various kinds of information relating to surgery in various forms such as a text, an image or a graph.

It is to be noted that the light source apparatus 11203 which supplies irradiation light when a surgical region is to be imaged to the endoscope 11100 may include a white light source which includes, for example, an LED, a laser light source or a combination of them. Where a white light source includes a combination of red, green, and blue (RGB) laser light sources, since the output intensity and the output timing can be controlled with a high degree of accuracy for each color (each wavelength), adjustment of the white balance of a picked up image can be performed by the light source apparatus 11203. Further, in this case, if laser beams from the respective RGB laser light sources are irradiated time-divisionally on an observation target and driving of the image pickup elements of the camera head 11102 are controlled in synchronism with the irradiation timings. Then images individually corresponding to the R, G and B colors can be also picked up time-divisionally. According to this method, a color image can be obtained even if color filters are not provided for the image pickup element.

Further, the light source apparatus 11203 may be controlled such that the intensity of light to be outputted is changed for each predetermined time. By controlling driving of the image pickup element of the camera head 11102 in synchronism with the timing of the change of the intensity of light to acquire images time-divisionally and synthesizing the images, an image of a high dynamic range free from underexposed blocked up shadows and overexposed highlights can be created.

Further, the light source apparatus 11203 may be configured to supply light of a predetermined wavelength band ready for special light observation. In special light observation, for example, by utilizing the wavelength dependency of absorption of light in a body tissue to irradiate light of a narrow band in comparison with irradiation light upon ordinary observation (namely, white light), narrow band observation (narrow band imaging) of imaging a predetermined tissue such as a blood vessel of a superficial portion of the mucous membrane or the like in a high contrast is performed. Alternatively, in special light observation, fluorescent observation for obtaining an image from fluorescent light generated by irradiation of excitation light may be performed. In fluorescent observation, it is possible to perform observation of fluorescent light from a body tissue by irradiating excitation light on the body tissue (autofluorescence observation) or to obtain a fluorescent light image by locally injecting a reagent such as indocyanine green (ICG) into a body tissue and irradiating excitation light corresponding to a fluorescent light wavelength of the reagent upon the body tissue. The light source apparatus 11203 can be configured to supply such narrow-band light and/or excitation light suitable for special light observation as described above.

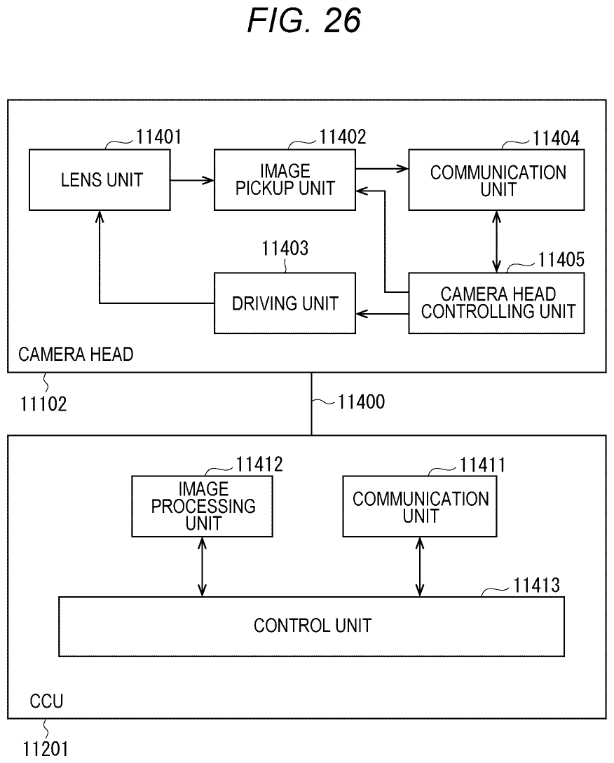

FIG. 26 is a block diagram illustrating an example of a functional configuration of the camera head 11102 and the CCU 11201 illustrated in FIG. 25.

The camera head 11102 includes a lens unit 11401, an image pickup unit 11402, a driving unit 11403, a communication unit 11404 and a camera head controlling unit 11405. The CCU 11201 includes a communication unit 11411, an image processing unit 11412 and a control unit 11413. The camera head 11102 and the CCU 11201 are connected for communication to each other by a transmission cable 11400.

The lens unit 11401 is an optical system, provided at a connecting location to the lens barrel 11101. Observation light taken in from a distal end of the lens barrel 11101 is guided to the camera head 11102 and introduced into the lens unit 11401. The lens unit 11401 includes a combination of a plurality of lenses including a zoom lens and a focusing lens.

The image pickup unit 11402 includes an image pickup element. The number of image pickup elements which is included by the image pickup unit 11402 may be one (single-plate type) or a plural number (multi-plate type). Where the image pickup unit 11402 is configured as that of the multi-plate type, for example, image signals corresponding to respective R, G and B are generated by the image pickup elements, and the image signals may be synthesized to obtain a color image. Alternatively, the image pickup unit 11402 may include a pair of image pickup elements for acquiring right-eye and left-eye image signals corresponding to three-dimensional (3D) display. If 3D display is performed, then the depth of a living body tissue in a surgical region can be comprehended more accurately by the surgeon 11131. It is to be noted that, where the image pickup unit 11402 is configured as that of stereoscopic type, a plurality of systems of lens units 11401 are provided corresponding to the individual image pickup elements.

Further, the image pickup unit 11402 may not necessarily be provided on the camera head 11102. For example, the image pickup unit 11402 may be provided immediately behind the objective lens in the inside of the lens barrel 11101.

The driving unit 11403 includes an actuator and moves the zoom lens and the focusing lens of the lens unit 11401 by a predetermined distance along an optical axis under the control of the camera head controlling unit 11405. Consequently, the magnification and the focal point of a picked up image by the image pickup unit 11402 can be adjusted suitably.

The communication unit 11404 includes a communication apparatus for transmitting and receiving various kinds of information to and from the CCU 11201. The communication unit 11404 transmits an image signal acquired from the image pickup unit 11402 as RAW data to the CCU 11201 through the transmission cable 11400.

In addition, the communication unit 11404 receives a control signal for controlling driving of the camera head 11102 from the CCU 11201 and supplies the control signal to the camera head controlling unit 11405. The control signal includes information relating to image pickup conditions such as, for example, information that a frame rate of a picked up image is designated, information that an exposure value upon image picking up is designated and/or information that a magnification and a focal point of a picked up image are designated.

It is to be noted that the image pickup conditions such as the frame rate, exposure value, magnification or focal point may be designated by the user or may be set automatically by the control unit 11413 of the CCU 11201 on the basis of an acquired image signal. In the latter case, an auto exposure (AE) function, an auto focus (AF) function and an auto white balance (AWB) function are incorporated in the endoscope 11100.

The camera head controlling unit 11405 controls driving of the camera head 11102 on the basis of a control signal from the CCU 11201 received through the communication unit 11404.

The communication unit 11411 includes a communication apparatus for transmitting and receiving various kinds of information to and from the camera head 11102. The communication unit 11411 receives an image signal transmitted thereto from the camera head 11102 through the transmission cable 11400.

Further, the communication unit 11411 transmits a control signal for controlling driving of the camera head 11102 to the camera head 11102. The image signal and the control signal can be transmitted by electrical communication, optical communication or the like.

The image processing unit 11412 performs various image processes for an image signal in the form of RAW data transmitted thereto from the camera head 11102.

The control unit 11413 performs various kinds of control relating to image picking up of a surgical region or the like by the endoscope 11100 and display of a picked up image obtained by image picking up of the surgical region or the like. For example, the control unit 11413 creates a control signal for controlling driving of the camera head 11102.

Further, the control unit 11413 controls, on the basis of an image signal for which image processes have been performed by the image processing unit 11412, the display apparatus 11202 to display a picked up image in which the surgical region or the like is imaged. Thereupon, the control unit 11413 may recognize various objects in the picked up image using various image recognition technologies. For example, the control unit 11413 can recognize a surgical tool such as forceps, a particular living body region, bleeding, mist when the energy device 11112 is used and so forth by detecting the shape, color and so forth of edges of objects included in a picked up image. The control unit 11413 may cause, when it controls the display apparatus 11202 to display a picked up image, various kinds of surgery supporting information to be displayed in an overlapping manner with an image of the surgical region using a result of the recognition. Where surgery supporting information is displayed in an overlapping manner and presented to the surgeon 11131, the burden on the surgeon 11131 can be reduced and the surgeon 11131 can proceed with the surgery with certainty.

The transmission cable 11400 which connects the camera head 11102 and the CCU 11201 to each other is an electric signal cable ready for communication of an electric signal, an optical fiber ready for optical communication or a composite cable ready for both of electrical and optical communications.

Here, while, in the example depicted, communication is performed by wired communication using the transmission cable 11400, the communication between the camera head 11102 and the CCU 11201 may be performed by wireless communication.

An example of the endoscopic surgery system to which the technology according to the present disclosure can be applied has been described above. The technology according to the present disclosure may be applied to the image pickup unit 11402 of the camera head 11102 in the configuration described above. Specifically, the photodetection device 1 described in the above-described embodiments and modifications can be applied to the image pickup unit 11402. By applying the technology according to the present disclosure to the image pickup unit 11402, for example, a more easily viewable captured image can be obtained, so that the operator can reliably check the surgical region.

Note that an endoscopic surgery system has been described as an example herein, but the technology according to the present disclosure may be applied to a microscopic surgery system or the like, for example.

### OTHER EMBODIMENTS

As described above, the present technology has been described by way of the first to fifth embodiments, but it should not be understood that the description and drawings constituting a part of this disclosure limit the present technology. Various alternative embodiments, examples, and operation techniques will be apparent to those skilled in the art from this disclosure.

For example, the technical ideas described in the first to fifth embodiments may be combined with each other. Various combinations in accordance with the respective technical ideas are possible.

Furthermore, the present technology can be applied to all kinds of photodetection devices including not only the above-described solid-state imaging device as an image sensor but also a ranging sensor also called a time of flight (ToF) sensor that measures distances, and the like. A ranging sensor is a sensor that emits irradiation light toward an object, detects reflected light that is the irradiation light reflected by a surface of the object, and calculates the distance to the object on the basis of a flight time since the emission of the irradiation light till the reception of the reflected light. As a structure of the ranging sensor, the structure of the pixel 3 described above may be employed.

Furthermore, in the above-described embodiment, the support substrate 40 is bonded to the wiring layer 30 on the side opposite to the semiconductor layer 20 side, but the photodetection device 1 may be a stacked CMOS image sensor (CIS) in which two or more semiconductor substrates are stacked on top of each other. In that case, at least one of the logic circuit 13 or the reading circuit 15 may be provided on a substrate different from the semiconductor substrate on which the cell region 20a is provided among these semiconductor substrates.

Furthermore, the materials mentioned as the materials forming the components described above may contain additives, impurities, or the like, for example.

As described above, it is needless to say that the present technology includes various embodiments and the like that are not described herein. Therefore, the technical scope of the present technology is defined only by the matters used to define the inventions disclosed in the claims considered appropriate from the above description.

Furthermore, the effects described herein are mere examples and are not restrictive, and there may be additional effects. Note that the present technology may also have the following configurations.

(1)

A photodetection device including:
a semiconductor layer including a plurality of cell regions arranged in a row direction and a column direction in a pixel region, one surface of the semiconductor layer being an element formation surface, and another surface of the semiconductor layer being a light incident surface; and
a deflection layer provided at a position facing the light incident surface of the cell region or provided in a portion of the cell region on the light incident surface side, in which
a photoelectric conversion element, a light shielding film extending along a direction perpendicular to a thickness direction of the semiconductor layer, and a charge holding unit located closer to the element formation surface than the light shielding film in a thickness direction of the semiconductor layer are provided in the cell region,
the deflection layer includes, for each of the cell regions, a first region having a first refractive index and a second region having a second refractive index higher than the first refractive index at different positions in plan view, and
the second region is located at a position overlapping the light shielding film in plan view.
   (2)

The photodetection device according to (1), in which
the light shielding film includes a first light shielding film and a second light shielding film located closer to the light incident surface than the first light shielding film in a thickness direction,
the first light shielding film and the first region are on one side of the cell region, and the second light shielding film and the second region are on another side of the cell region in plan view, and
the second region is located at a position overlapping the second light shielding film in plan view.
   (3)

The photodetection device according to (2), in which
the charge holding unit is at a position closer to the one side of the cell region in plan view, and
the first light shielding film and the first region are at positions overlapping the charge holding unit in plan view.
   (4)

The photodetection device according to (2) or (3), in which
the cell region has a quadrangular shape in plan view and includes a first corner and a second corner that face each other, and
the one side of the cell region is the first corner side, and the another side of the cell region is the second corner side.
   (5)

The photodetection device according to (4), in which
the charge holding unit is at a position closer to the first corner in plan view, and
the first light shielding film and the first region are at positions overlapping the charge holding unit in plan view.
   (6)

The photodetection device according to (4) or (5), in which
the semiconductor layer includes a plurality of cell region assemblies including four of the cell regions in two rows and two columns and arranged in a row direction and a column direction,
the second corner of each of the four cell regions constituting one of the cell region assemblies is a corner located closer to a center of the cell region assembly, and the first corner of each of the four cell regions constituting one of the cell region assemblies is a corner located closer to a corner of the cell region assembly, and
the second region is provided collectively for each of the cell region assemblies, and overlaps all the second corners for each of the cell region assemblies in plan view.
   (7)

The photodetection device according to (1), in which
the light shielding film includes only one layer of film containing one light shielding material,
the light shielding film and the second region are on one side of the cell region and the first region is on another side of the cell region in plan view,
the charge holding unit is at a position closer to the one side of the cell region in plan view, and
the light shielding film and the second region are at positions overlapping the charge holding unit in plan view.
   (8)

The photodetection device according to (7), in which
the cell region has a quadrangular shape in plan view and includes a first corner and a second corner that face each other, and
the one side of the cell region is the first corner side, and the another side of the cell region is the second corner side.
   (9)

The photodetection device according to (8), in which
the semiconductor layer includes a plurality of cell region assemblies including four of the cell regions in two rows and two columns and arranged in a row direction and a column direction,
the first corner of each of the four cell regions constituting one of the cell region assemblies is a corner located closer to a center of the cell region assembly, and the second corner of each of the four cell regions constituting one of the cell region assemblies is a corner located closer to a corner of the cell region assembly, and
the second region is provided collectively for each of the cell region assemblies, and overlaps all the first corners for each of the cell region assemblies in plan view.
   (10)

The photodetection device according to any one of (1) to (9), in which
the deflection layer is provided at a position facing the light incident surface of the cell region, and includes a first material and a second material having a refractive index higher than that of the first material, and
the first region contains the first material, and the second region contains the second material.
   (11)

The photodetection device according to any one of (1) to (9), in which
the deflection layer is provided at a position facing the light incident surface of the cell region, and includes a first material and a second material having a refractive index higher than that of the first material, and
a thickness of the second material in the second region is thicker than a thickness of the second material in the first region.
   (12)

The photodetection device according to (11), in which a thickness of the second material gradually decreases from the second region toward the first region.

(13)

The photodetection device according to any one of (1) to (5), (7), and (8), in which
the deflection layer is provided in a portion of the cell region on the light incident surface side and includes a plurality of columnar bodies extending from the light incident surface in a thickness direction of the semiconductor layer for each of the cell regions,
a refractive index of a material constituting the columnar body is different from a refractive index of the semiconductor layer, and
a density of the columnar bodies provided in the first region is different from a density of the columnar bodies provided in the second region.
   (14)

The photodetection device according to (13), in which
a refractive index of a material constituting the columnar body is lower than a refractive index of the semiconductor layer, and
a density of the columnar bodies provided in the first region is higher than a density of the columnar bodies provided in the second region.
   (15)

The photodetection device according to (13) or (14), including a color filter provided on a side opposite to the semiconductor layer side of the deflection layer, in which
the cell region includes a first cell region, a second cell region, and a third cell region,
the color filter includes a first filter for first color light provided for the first cell region, a second filter for second color light provided for the second cell region and having a wavelength shorter than a wavelength of the first color light, and a third filter for third color light provided for the third cell region and having a wavelength shorter than a wavelength of the second color light,
a refractive index difference between the first region and the second region of the deflection layer provided in the first cell region is larger than a refractive index difference between the first region and the second region of the deflection layer provided in the second cell region, and
a refractive index difference between the first region and the second region of the deflection layer provided in the second cell region is larger than a refractive index difference between the first region and the second region of the deflection layer provided in the third cell region.
   (16)

The photodetection device according to (13) or (14), including a color filter provided on a side opposite to the semiconductor layer side of the deflection layer,
the cell region includes a first cell region, a second cell region, and a third cell region,
the color filter includes a first filter for first color light provided for the first cell region, a second filter for second color light provided for the second cell region and having a wavelength shorter than a wavelength of the first color light, and a third filter for third color light provided for the third cell region and having a wavelength shorter than a wavelength of the second color light, and
the deflection layer is provided only for the first cell region or only for the first cell region and the second cell region.
   (17)

The photodetection device according to (15) or (16), in which the first color light is red, the second color light is green, and the third color light is blue.

(18)

The photodetection device according to (6) or (9), in which
in the cell region assembly located in a central portion of the pixel region, a center of the second region is at a center of the cell region assembly in plan view, and
in the cell region assembly located closer to an edge than the central portion of the pixel region, a center of the second region is at a position closer to the central portion of the pixel region than a center of the cell region assembly in plan view.
   (19)
   The photodetection device according to any one of (1) to (18), in which the cell region includes a first transistor capable of transferring a signal charge from the photoelectric conversion element to the charge holding unit, a charge accumulation region, and a second transistor capable of transferring a signal charge from the charge holding unit to the charge accumulation region.
   (20)

An electronic apparatus including:
a photodetection device; and
an optical system that causes the photodetection device to form an image of image light from a subject, in which
the photodetection device includes:
   a semiconductor layer including a plurality of cell regions arranged in a row direction and a column direction in a pixel region, one surface of the semiconductor layer being an element formation surface, and another surface of the semiconductor layer being a light incident surface; and
   a deflection layer provided at a position facing the light incident surface of the cell region or provided in a portion of the cell region on the light incident surface side,
a photoelectric conversion element, a light shielding film extending along a direction perpendicular to a thickness direction of the semiconductor layer, and a charge holding unit located closer to the element formation surface than the light shielding film in a thickness direction of the semiconductor layer are provided in the cell region,
the deflection layer includes, for each of the cell regions, a first region having a first refractive index and a second region having a second refractive index higher than the first refractive index at different positions in plan view, and the second region is located at a position overlapping the
light shielding film in plan view.

The scope of the present technology is not limited to the exemplary embodiments illustrated in the drawings and described above, but includes also all embodiments that produce effects equivalent to the effects that the present technology intends to produce. Moreover, the scope of the present technology is not limited to the combinations of the features of the invention defined by the claims, and may be defined by any desired combination of specific features among all the disclosed features.

### REFERENCE SIGNS LIST

1 Photodetection device
2 Semiconductor chip
3 Pixel
4 Vertical drive circuit
5 Column signal processing circuit
6 Horizontal drive circuit
7 Output circuit
8 Control circuit
10 Pixel drive line
11 Vertical signal line
12 Horizontal signal line
13 Logic circuit
14 Bonding pad
15 Circuit
20 Semiconductor layer
20a Cell region
20a1 First cell region
20a2 Second cell region
20a3 Third cell region
20b Isolation region
30 Wiring layer
50 Light shielding unit
51 Partition wall
51a First partition wall
51b Second partition wall
52 Light shielding film
52a First light shielding film
52b Second light shielding film
53 Inter-pixel light-shielding film
60 Light incident surface side multilayer body
62 Insulating layer
64 Color filter
64R First filter
64G Second filter
64B Third filter
65 Microlens
70 Deflection layer
71 First region
72 Second region
73 Member
74 Columnar body
100 Electronic apparatus
101 Solid-state imaging device
102 Optical system (optical lens)
103 Shutter device
104 Drive circuit
105 Signal processing circuit
106 Incident light
AMP Amplification transistor
B1, B2 Cell region assembly
Ca, Cb Cross center
FD Charge accumulation region
L1 Main light beam
LNZ Inner lens
MEM Charge holding unit
PD Photoelectric conversion element
S1 First surface
S2 Second surface
OFG Discharge transistor
RST Reset transistor
SEL Selection transistor
TRG Third transfer transistor
TRM Second transfer transistor
TRX First transfer transistor
TRXG Vertical gate electrode

1. A photodetection device comprising:
a semiconductor layer including a plurality of cell regions arranged in a row direction and a column direction in a pixel region, one surface of the semiconductor layer being an element formation surface, and another surface of the semiconductor layer being a light incident surface; and
a deflection layer provided at a position facing the light incident surface of the cell region or provided in a portion of the cell region on the light incident surface side, wherein
a photoelectric conversion element, a light shielding film extending along a direction perpendicular to a thickness direction of the semiconductor layer, and a charge holding unit located closer to the element formation surface than the light shielding film in a thickness direction of the semiconductor layer are provided in the cell region,
the deflection layer includes, for each of the cell regions, a first region having a first refractive index and a second region having a second refractive index higher than the first refractive index at different positions in plan view, and
the second region is located at a position overlapping the light shielding film in plan view.

2. The photodetection device according to claim 1, wherein
the light shielding film includes a first light shielding film and a second light shielding film located closer to the light incident surface than the first light shielding film in a thickness direction,
the first light shielding film and the first region are on one side of the cell region, and the second light shielding film and the second region are on another side of the cell region in plan view, and
the second region is located at a position overlapping the second light shielding film in plan view.

3. The photodetection device according to claim 2, wherein
the charge holding unit is at a position closer to the one side of the cell region in plan view, and
the first light shielding film and the first region are at positions overlapping the charge holding unit in plan view.

4. The photodetection device according to claim 2, wherein
the cell region has a quadrangular shape in plan view and includes a first corner and a second corner that face each other, and
the one side of the cell region is the first corner side, and the another side of the cell region is the second corner side.

5. The photodetection device according to claim 4, wherein
the charge holding unit is at a position closer to the first corner in plan view, and
the first light shielding film and the first region are at positions overlapping the charge holding unit in plan view.

6. The photodetection device according to claim 4, wherein
the semiconductor layer includes a plurality of cell region assemblies including four of the cell regions in two rows and two columns and arranged in a row direction and a column direction,
the second corner of each of the four cell regions constituting one of the cell region assemblies is a corner located closer to a center of the cell region assembly, and the first corner of each of the four cell regions constituting one of the cell region assemblies is a corner located closer to a corner of the cell region assembly, and
the second region is provided collectively for each of the cell region assemblies, and overlaps all the second corners for each of the cell region assemblies in plan view.

7. The photodetection device according to claim 1, wherein
the light shielding film includes only one layer of film containing one light shielding material,
the light shielding film and the second region are on one side of the cell region and the first region is on another side of the cell region in plan view,
the charge holding unit is at a position closer to the one side of the cell region in plan view, and
the light shielding film and the second region are at positions overlapping the charge holding unit in plan view.

8. The photodetection device according to claim 7, wherein
the cell region has a quadrangular shape in plan view and includes a first corner and a second corner that face each other, and
the one side of the cell region is the first corner side, and the another side of the cell region is the second corner side.

9. The photodetection device according to claim 8, wherein
the semiconductor layer includes a plurality of cell region assemblies including four of the cell regions in two rows and two columns and arranged in a row direction and a column direction,
the first corner of each of the four cell regions constituting one of the cell region assemblies is a corner located closer to a center of the cell region assembly, and the second corner of each of the four cell regions constituting one of the cell region assemblies is a corner located closer to a corner of the cell region assembly, and
the second region is provided collectively for each of the cell region assemblies, and overlaps all the first corners for each of the cell region assemblies in plan view.

10. The photodetection device according to claim 1, wherein
the deflection layer is provided at a position facing the light incident surface of the cell region, and includes a first material and a second material having a refractive index higher than that of the first material, and
the first region contains the first material, and the second region contains the second material.

11. The photodetection device according to claim 1, wherein
the deflection layer is provided at a position facing the light incident surface of the cell region, and includes a first material and a second material having a refractive index higher than that of the first material, and
a thickness of the second material in the second region is thicker than a thickness of the second material in the first region.

12. The photodetection device according to claim 11, wherein a thickness of the second material gradually decreases from the second region toward the first region.

13. The photodetection device according to claim 1, wherein
the deflection layer is provided in a portion of the cell region on the light incident surface side and includes a plurality of columnar bodies extending from the light incident surface in a thickness direction of the semiconductor layer for each of the cell regions,
a refractive index of a material constituting the columnar body is different from a refractive index of the semiconductor layer, and
a density of the columnar bodies provided in the first region is different from a density of the columnar bodies provided in the second region.

14. The photodetection device according to claim 13, wherein
a refractive index of a material constituting the columnar body is lower than a refractive index of the semiconductor layer, and
a density of the columnar bodies provided in the first region is higher than a density of the columnar bodies provided in the second region.

15. The photodetection device according to claim 13, comprising a color filter provided on a side opposite to the semiconductor layer side of the deflection layer, wherein
the cell region includes a first cell region, a second cell region, and a third cell region,
the color filter includes a first filter for first color light provided for the first cell region, a second filter for second color light provided for the second cell region and having a wavelength shorter than a wavelength of the first color light, and a third filter for third color light provided for the third cell region and having a wavelength shorter than a wavelength of the second color light,
a refractive index difference between the first region and the second region of the deflection layer provided in the first cell region is larger than a refractive index difference between the first region and the second region of the deflection layer provided in the second cell region, and
a refractive index difference between the first region and the second region of the deflection layer provided in the second cell region is larger than a refractive index difference between the first region and the second region of the deflection layer provided in the third cell region.

16. The photodetection device according to claim 13, comprising a color filter provided on a side opposite to the semiconductor layer side of the deflection layer, wherein
the cell region includes a first cell region, a second cell region, and a third cell region,
the color filter includes a first filter for first color light provided for the first cell region, a second filter for second color light provided for the second cell region and having a wavelength shorter than a wavelength of the first color light, and a third filter for third color light provided for the third cell region and having a wavelength shorter than a wavelength of the second color light, and
the deflection layer is provided only for the first cell region or only for the first cell region and the second cell region.

17. The photodetection device according to claim 16, wherein the first color light is red, the second color light is green, and the third color light is blue.

18. The photodetection device according to claim 6, wherein
in the cell region assembly located in a central portion of the pixel region, a center of the second region is at a center of the cell region assembly in plan view, and
in the cell region assembly located closer to an edge than the central portion of the pixel region, a center of the second region is at a position closer to the central portion of the pixel region than a center of the cell region assembly in plan view.

19. The photodetection device according to claim 1, wherein the cell region includes a first transistor capable of transferring a signal charge from the photoelectric conversion element to the charge holding unit, a charge accumulation region, and a second transistor capable of transferring a signal charge from the charge holding unit to the charge accumulation region.

20. An electronic apparatus comprising:
a photodetection device; and
an optical system that causes the photodetection device to form an image of image light from a subject, wherein
the photodetection device includes:
a semiconductor layer including a plurality of cell regions arranged in a row direction and a column direction in a pixel region, one surface of the semiconductor layer being an element formation surface, and another surface of the semiconductor layer being a light incident surface; and
a deflection layer provided at a position facing the light incident surface of the cell region or provided in a portion of the cell region on the light incident surface side,
a photoelectric conversion element, a light shielding film extending along a direction perpendicular to a thickness direction of the semiconductor layer, and a charge holding unit located closer to the element formation surface than the light shielding film in a thickness direction of the semiconductor layer are provided in the cell region,
the deflection layer includes, for each of the cell regions, a first region having a first refractive index and a second region having a second refractive index higher than the first refractive index at different positions in plan view, and
the second region is located at a position overlapping the light shielding film in plan view.
